(19) United States
(12) Patent Application Publication
(10) Pub. No.: US 2016/0178467 A1
(43) Pub. Date: Jun. 23, 2016

(54) PRESSURE SENSOR HAVING CAP-DEFINED MEMBRANE

(71) Applicant: Silicon Microstructures, Inc., Milpitas, CA (US)

(72) Inventors: Steve Terry, Palo Alto, CA (US); Fernando Alfaro, Redwood City, CA (US); Marc Konradt, Fremont, CA (US)

(73) Assignee: Silicon Microstructures, Inc., Milpitas, CA (US)

(21) Appl. No.: 15/040,899

(22) Filed: Feb. 10, 2016

Related U.S. Application Data
(63) Continuation-in-part of application No. 14/622,576, filed on Feb. 13, 2015.
(60) Provisional application No. 62/240,782, filed on Oct. 13, 2015.
(60) Provisional application No. 62/030,604, filed on Jul. 29, 2014.
(60) Provisional application No. 62/090,306, filed on Dec. 10, 2014.

(51) Int. Cl. G01L 9/00; B81B 7/00

(52) U.S. Cl. CPC G01L 9/0048; G01L 9/0051; B81B 7/0016; B81B 2201/0264; B81B 2203/0127; B81B 2207/03; B81B 2207/07

(57) ABSTRACT

Structures and methods of protecting membranes on pressure sensors. One example may provide a pressure sensor having a backside cavity defining a frame and under a membrane formed in a device layer. The sensor may further include a cap joined to the device layer by a bonding layer. A recess for a reference cavity may be formed in one or more of the cap, bonding layer, and membrane or other device layer portion. The recess may have a width that is narrower than a width of the backside cavity in at least one direction. A eutectically bondable metal stack may be provided on a bottom side of the sensor. Conductive traces in the sensor may be formed by implanting and annealing ions. An implanted field shield may be formed to protect the conductive traces that form sense elements. Damage prevention circuitry and a temperature sensing diode may also be provided.

### CROSS-REFERENCE TO RELATED APPLICATION

This application claims priority to U.S. Provisional Application Ser. No. 62/240,782 filed Oct. 13, 2015, and is a continuation-in-part of U.S. patent application Ser. No. 14/622,576, filed on Feb. 13, 2015, which claims priority to U.S. provisional application Ser. Nos. 62/030,604, filed Jul. 29, 2014, and 62/090,306, filed Dec. 10, 2014, the entireties of each are incorporated herein by reference.

### BACKGROUND

Pressure sensing devices have become ubiquitous the past few years as they have found their way into many types of products. Utilized in automotive, industrial, consumer, and medical products, the demand for pressure sensing devices has skyrocketed and shows no signs of abating.

Pressure sensing devices may include pressure sensors as well as other components. Pressure sensors may typically include a diaphragm or membrane. Typically, this membrane is formed by creating the Wheatstone bridge in a silicon wafer, then etching away the silicon from the opposite surface until a thin layer of silicon is formed beneath the Wheatstone bridge. The thin layer is a membrane that may be surrounded by a thicker, non-etched silicon water portion forming a frame. When a pressure sensor in a pressure sensing device experiences a pressure, the membrane may respond by changing shape. This change in shape causes one or more characteristics of electronic components on the membrane to change. These changing characteristics can be measured, and from these measurements, the pressure can be determined.

Often, the electronic components are resistors that are configured as a Wheatstone bridge located on the membrane. As the membrane distorts under pressure, the resistance of the resistors also changes. This change results in an output of the Wheatstone bridge. This change can be measured through wires or leads attached to the resistors.

Conventional pressure sensors may be formed of a diaphragm or membrane attached to and surrounded by a frame. In some pressure sensors, the sensor may measure a pressure difference between two different locations, such as the two sides of a filter. These may be referred to as gauge pressure sensors. In other types of sensors, an output may be compared to a known, consistent pressure, which may typically be a vacuum. This type of sensor may be referred to as an absolute pressure sensor. In an absolute pressure sensor, a first side of the membrane may be exposed to the media to be measured, while a second side may be in contact with the reference chamber, which may be a vacuum chamber. The first side of the membrane exposed to the media may be subjected to high pressures.

This high pressure on the membrane may result in a highly concentrated tensile force at the frame-membrane junction. This stress may create cracks or other damage in the silicon crystal structure of the membrane. This damage may lead to errors in pressure measurements or non-functionality of the pressure sensor.

Metals for bonding a pressure sensor to another device may be forced into the cavity or distributed along a sidewall of the sensor during various processing steps, thereby causing electrical shorts or other damage to the sensor.

Undesirable electrical charges may affect the sense elements if they are not shielded properly. And electrostatic discharge may damage the sensor or its components.

Additionally, it may be desirable to provide temperature sensing.

Thus, what is needed are structures and methods of protecting a membrane on a pressure sensor from damage due to high pressures. In some embodiments, formation of a bondable metal stack that will avoid shorts is needed. In certain embodiments, a field shield is needed. In various embodiments, a temperature sensor and/or circuitry that prevents damage from electrostatic discharge is needed.

For the avoidance of doubt, the above-described contextual background shall not be considered limiting on any of the below-described embodiments, as described in more detail below.

### SUMMARY

The following presents a simplified summary of the specification in order to provide a basic understanding of some aspects of the specification. This summary is not an extensive overview of the specification. It is intended to neither identify key or critical elements of the specification nor delineate the scope of any particular embodiments of the specification, or any scope of the claims. Its sole purpose is to present some concepts of the specification in a simplified form as a prelude to the more detailed description that is presented in this disclosure.

Accordingly, embodiments of the present invention may provide structures and methods of protecting a membrane on a pressure sensor from damage due to high pressures. An illustrative example may provide a pressure sensor having a first wafer portion including a handle wafer or layer and a device wafer or layer, the handle wafer or layer having a backside cavity, the backside cavity defining a membrane in the device wafer or layer. The pressure sensor may further include a bonding layer over the membrane and a cap over or attached to the bonding layer. The bonding layer may be an oxide layer formed on the device wafer, the cap wafer, or both. In various embodiments of the present invention, a reference cavity may be formed in one or more of the membrane, the bonding layer, the cap, or other layer or portion of the pressure sensor. The reference cavity, regardless of which layer or layers in which it resides, may have a lateral or planar width that is narrower than a width of the backside cavity in at least one direction. In other embodiments, the reference cavity may be shaped such that it has an outer edge that is within an outer edge of the backside cavity. This may provide reinforcement and reduce stress at a junction of the membrane and frame. Also, the narrower reference cavity may define an active portion of the membrane such that the active portion of the membrane is spaced away from the device layer and backside cavity junction. (As used here, a membrane may be defined by a backside cavity and a frame, while a portion of the membrane, the active membrane, may be defined by a reference cavity. Also as used here, the more general term membrane may mean either membrane or active membrane, particularly where the distinction is not critical.) In various embodiments of the present invention, the device wafer or layer may be formed of a silicon wafer portion or other material, the bonding layer may comprise silicon dioxide or glass or other material, while the cap or cap layer may be formed of a silicon wafer portion, silicon dioxide or glass, or other glass, including a heat-resistant glass with a low temperature coefficient or temperature coefficient close to that of silicon, such as a borosilicate glass including Pyrex®, which is licensed by Corning Incorporated, or other material.

Embodiments of the present invention may provide sensors that simplify manufacturing. Again, a membrane on a sensor may be fabricated by first creating a Wheatstone bridge in a silicon wafer, and then etching away the silicon beneath the Wheatstone bridge to form a thin membrane of silicon containing the Wheatstone bridge. One factor affecting the sensitivity of the device may be the proximity of the resistors of the Wheatstone bridge to the edges of the active membrane. Embodiments of the present invention may provide a pressure sensor in which the edges of an active portion of the membrane are determined by the location of the reference cavity, rather than the backside cavity cut from the back of the silicon. Because the reference cavity is much thinner than the cavity cut from the backside of the silicon, it may be easier to align the Wheatstone bridge to the edges of the active membrane during manufacturing. The relative thinness of the reference cavity may also help in controlling the size of the cavity. Moreover, the reference cavity and the Wheatstone bridge may be on the same side of the device, rather than on opposite sides, which may make them easier to align. Also, by locating the reference cavity in the device wafer or bonding layer on the device wafer, alignment during bonding may not be as critical as compared to when a reference cavity is etched into a cap layer or wafer, since this second configuration may require the alignment of two wafers during bonding.

Embodiments of the present invention may also provide pressure sensors that are protected from damage by high pressures in at least two ways. In conventional pressure sensors, the size of the membrane may be determined by the size of the cavity etched into the backside of the wafer. In various embodiments of the present invention, this restriction on the size of the backside cavity may be removed. Significantly, the size of the active portion of the membrane is no longer determined by the size of the backside cavity, and thus the size of the backside cavity can be made much larger than the size of the active portion of the membrane. As the size of the backside cavity increases, a tensile stress generated at the corner of the backside cavity may be reduced. Also, the edge of the active membrane, where the most stress is generated, is no longer proximate with the corner of the back cavity. Thus, the highest stress may not only be reduced, but the locus of the highest stress may shift to a top side corner of the active membrane, and this stress may be compressive rather than tensile. Silicon can withstand a higher compressive stress than tensile stress before fracturing, further protecting the device from damage.

Embodiments of the present invention may also limit damage caused by high pressures of fluids in the backside cavity by limiting an amount the membrane may deflect. Specifically, the reference cavity above the active portion of the membrane may have a height or thickness such that it may limit the deflection of the membrane. This may prevent the membrane from deflecting more than an amount where damage may occur due to high or excessively high pressures. In a specific embodiment of the present invention, it may be desirable that the membrane deflect a first distance during normal operation. It may also be expected that damage may occur if the membrane is allowed to deflect a second distance, the second distance greater than the first. In this example, the reference cavity may have a thickness or height such that the membrane is prevented from deflecting more than a third distance, the third distance greater than the first distance to allow desired operation, but less than the second distance to prevent damage.

In various embodiments of the present invention, various layers may be included or omitted in embodiments of the present invention. For example, an optional layer of eutectically bondable metal or other material may be placed on the back or bottom of the device. This layer may be formed as a thin layer of gold on the back or bottom of the device for bonding purposes. This layer may facilitate bonding to a second integrated circuit device, a device package, a device enclosure, or a printed or flexible circuit board or other substrate. An optional layer of polysilicon or other material may be placed or formed on a top surface of device layer or wafer. This optional layer may be located on a top surface of the device layer and under the bonding or oxide layer. That is, optional layer may be located between device layer or wafer and bonding or oxide layer.

Various embodiments of the present invention may incorporate one or more of these and the other features described herein. A better understanding of the nature and advantages of the present invention may be gained by reference to the following detailed description and the accompanying drawings.

The following description and the drawings set forth certain illustrative aspects of the specification. These aspects are indicative, however, of but a few of the various ways in which the principles of the specification may be employed. Other advantages and novel features of the specification will become apparent from the following detailed description of the specification when considered in conjunction with the drawings.

### BRIEF DESCRIPTION OF THE DRAWINGS

FIG. 1 illustrates a side view of a pressure sensor according to an embodiment of the present invention;

FIG. 2 illustrates a top view of a pressure sensor according to an embodiment of the present invention;

FIG. 3 illustrates a portion of a pressure sensor being manufactured according to an embodiment of the present invention;

FIG. 4 illustrates a portion of a pressure sensor being manufactured according to an embodiment of the present invention;

FIG. 5 illustrates a portion of a pressure sensor being manufactured according to an embodiment of the present invention;

FIG. 6 illustrates a portion of a pressure sensor being manufactured according to an embodiment of the present invention;

FIG. 7 illustrates a side view of a portion of a pressure sensor according to an embodiment of the present invention;

FIG. 8 illustrates a side view of a pressure sensor according to an embodiment of the present invention;

FIG. 9 illustrates a portion of a pressure sensor being manufactured according to an embodiment of the present invention;

FIG. 10 illustrates a portion of a pressure sensor being manufactured according to an embodiment of the present invention;

FIG. 11 illustrates a side view of a portion of a pressure sensor according to an embodiment of the present invention;

FIG. 12 illustrates a side view of a portion of a pressure sensor according to an embodiment of the present invention;

FIG. 13 illustrates a side view of another pressure sensor according to an embodiment of the present invention;

FIG. 14 illustrates a top view of a pressure sensor according to an embodiment of the present invention;

FIG. 15 illustrates a portion of a pressure sensor being manufactured according to an embodiment of the present invention;

FIG. 16 illustrates a side view of another pressure sensor according to an embodiment of the present invention;

FIG. 17 illustrates a top view of a pressure sensor according to an embodiment of the present invention;

FIG. 18 illustrates a portion of a pressure sensor being manufactured according to an embodiment of the present invention;

FIG. 19 illustrates a portion of a pressure sensor being manufactured according to an embodiment of the present invention;

FIG. 20 illustrates a portion of a pressure sensor being manufactured according to an embodiment of the present invention;

FIG. 21 illustrates a side view of another pressure sensor according to an embodiment of the present invention;

FIGS. 22-24 illustrate a side view of another pressure sensor according to an embodiment of the present invention;

FIGS. 25-31 illustrate side views of formation of a structure that may be used in a pressure sensor according to the present invention;

FIGS. 32 and 33A illustrate overhead views of structures for use in the pressure sensors of the present invention;

FIG. 33B and 33C illustrate schematics of the resistors and other structures that may be used in the pressure sensors of the present invention;

FIG. 34 illustrates an overhead view of a combination of FIGS. 2, 32 and 33A;

FIGS. 35-38 illustrate a side view of the formation of a field shield according to an embodiment of the present invention; and

FIGS. 39-41 illustrate overhead views and a side view of a diode according to an embodiment of the present invention.

### DETAILED DESCRIPTION OF ILLUSTRATIVE EMBODIMENTS

The various embodiments are now described with reference to the drawings, wherein like reference numerals are used to refer to like elements throughout. In the following description, for purposes of explanation, numerous specific details are set forth in order to provide a thorough understanding of the various embodiments. It may be evident, however, that the various embodiments can be practiced without these specific details. In other instances, well-known structures and devices are shown in block diagram form in order to facilitate describing the various embodiments.

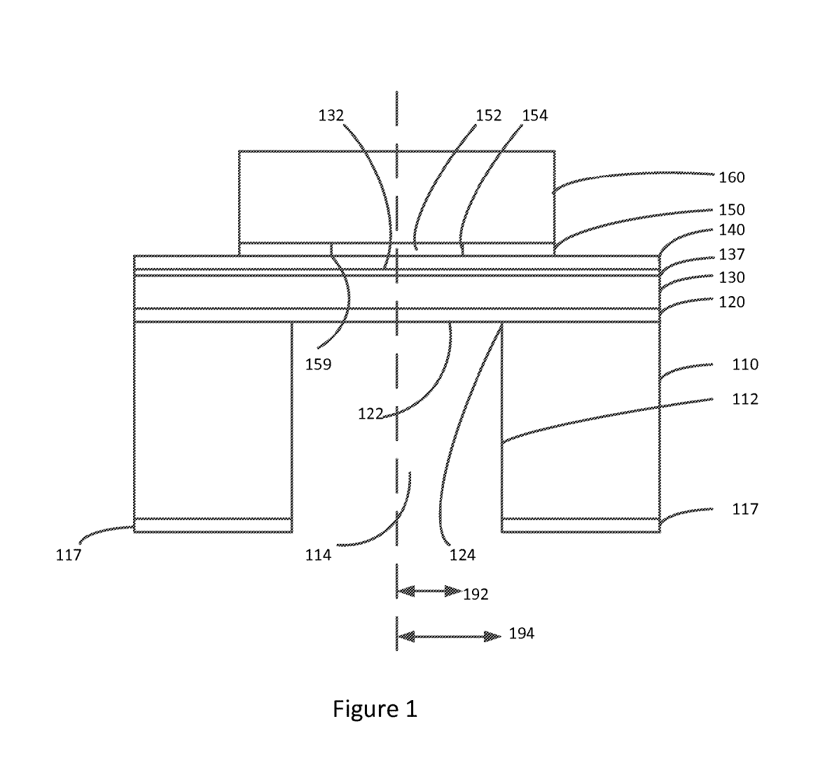

FIG. 1 illustrates a side view of a pressure sensor according to an embodiment of the present invention. This figure, as with the other included figures, is shown for illustrative purposes and does not limit either the possible embodiments of the present invention or the claims.

This pressure sensor may include cap 160 attached to a top of a first wafer portion of a pressure sensor, where the first wafer portion further includes device wafer or layer 130 and handle wafer or layer 110. Device wafer of layer 130 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though oxide layer 150 may be omitted in various embodiments of the present invention. Cap 160 may be attached to device layer 130 by fusion bonding oxide layer 150 to oxide layer 140. Where one or more oxide layers 140 or 150 are omitted, cap 160 may be attached to device layer 130 by fusion bonding cap 160 to oxide layer 140, by fusion bonding oxide layer 150 to device layer 130, or by fusion bonding cap layer 160 directly to device layer 130. Oxide layer 150 may be etched before fusion bonding to form a recess, which may form reference cavity 152. Reference cavity 152 may be defined by outer edge 154. While reference cavity 152 is formed in oxide layer 150, in this and other embodiments of the present invention, reference cavity 152 may be formed in oxide layer 150 and cap layer 160, in oxide layer 150 and oxide layer 140, in device layer 130, or in any combination thereof.

Reference cavity 152 may have a width that is narrower than a width of backside cavity 114 in at least one direction. Specifically, a distance 192 from a center line of the pressure sensor to an edge 154 of reference cavity 152 may be shorter than a distance 194 from a center line to an edge 112 of backside cavity 114. In this way, an active portion of a membrane defined by edge 154 may be narrower than the membrane defined by edge 112. In various embodiments of the present invention, an outside edge of reference cavity 152 may be inside of an edge of backside cavity 114, where the edges are considered vertically in this and other embodiments.

In conventional pressure sensors, cap 160 may be absent. In such case, as a membrane or diaphragm formed by a backside cavity deflects, a junction point between a diaphragm and frame may experience a large tensile force. In this figure, if cap 160 were absent, this force would be concentrated at location 124. This concentration of force may result in cracks or other damage at or near location 124.

Accordingly, embodiments of the present invention may provide a cap or other reinforcing structure, such as cap 160, where a reference cavity, such as reference cavity 152, may be narrower than a backside cavity, such as backside cavity 114. In this case, location 124 may be reinforced by cap 160. Also, the location of highest stress may move from the location 124 to location 159. The stress at location 159 is compressive when pressure is applied to the underside of membrane 122, rather than tensile. Further, even when one or more cracks or other damage appears at or near location 124, the cracks are away from the active membrane area, which is defined by reference cavity 152.

Also, in conventional pressure sensors, a membrane or diaphragm may deflect an amount that may cause damage to the pressure sensor. This may occur due to the presence of unforeseen high pressures of fluids in the backside cavity, or by another event.

Accordingly, embodiments of the present invention may provide a reference cavity having height or thickness that limits a maximum deflection of the active membrane. In various embodiments of the present invention, this height or thickness may be such that an active membrane may be able to deflect enough for desired operation, but not enough to cause damage to the pressure sensor. Specifically, edge 154 may have a height that allows the active membrane to deflect enough for proper operation of the pressure sensor, but not enough to cause damage or rupture the membrane. Instead, the active membrane deflects such that it reaches a top of the reference cavity 1 52 and cannot go any further even if the pressure continues to increase, preventing damage from being caused. That is, the top of the reference cavity 152 may act as a deflection stop to prevent damage to the pressure sensor. In various embodiments of the present invention, the topside of reference cavity 152, the underside of cap 160, may include one or more bosses or other structures that may determine a height of the reference cavity 152 and the maximum deflection of the active membrane.

In various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 136, as with the other reference cavities in other embodiments of the present invention, may have a thickness or height of 100 nm to 500 nm, though in other embodiments may it may be from 50 nm to 1000 nm. A specific embodiment of the present invention may have a reference cavity having a height of 4000 A.

In this and other embodiments of the present invention, an optional layer 117 of eutectically-bondable metal or other material may be placed on the back or bottom of handle wafer 110. This layer may be formed as a thin layer of gold on the back or bottom of the device for bonding purposes. Layer 117 may facilitate bonding to a second integrated circuit device, a device package, a device enclosure, or a printed or flexible circuit board or other substrate. Optional layer 117 has been omitted from the other figures for clarity.

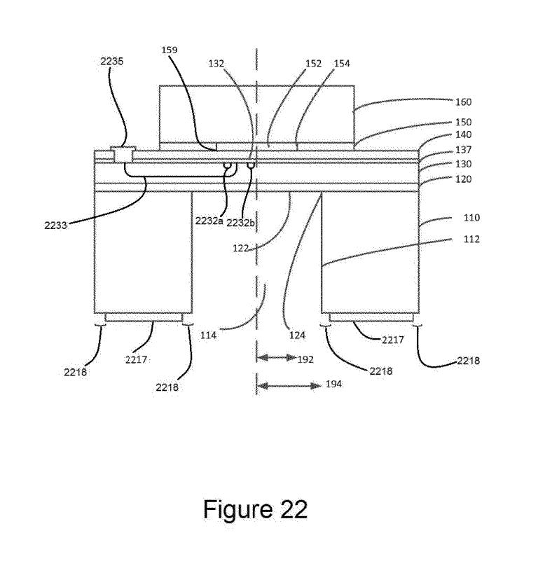

Referring now to FIGS. 22-24, in certain embodiments of the invention, optional layer 117 may be formed in the manner referenced as bondable metal layer 2217. By adding metal layer 2217 to the sensor die, it is possible to use eutectic solder on a substrate 2371a, 2371b to attach the sensor die to the substrate 2371a, 2371b via metal layer 2217 via soldering. Eutectic solder may be preformed on the substrate, and at the time of soldering, the solder may be melted such that the eutectic solder adheres to the metal layer 2217 when the metal layer 2217 is placed in contact with the eutectic solder and appropriate force applied. For some embodiments of the invention, the solder and metal layer 2217 are placed in contact prior to heating, followed by the application of heat to the solder and metal layer 2217 simultaneously, such that the solder will melt and bond to the metal layer 2217.

Specifically, a solder preform 2373a, 2373b, 2375a, 2375b is deposited, stamped, or otherwise formed on substrate 2371a, 2371b in a pattern intended to match the footprint of metal layer 2217. The solder pattern may be rectangular, circular, or any number of patterns in which the footprint of a die may be formed.

The metal layer 2217 is formed on the bottom side of the handle wafer 110 to adhere more strongly than would solder to the oxide or silicon on the bottom of wafer 110. The metal layer 2217 may be formed as a gold layer or as a combination of metals. One preferably metal combination for use in forming metal layer 2217 is co-deposited Ti-Tungsten alloy sputtered onto the bottom of handle wafer 110, followed by gold sputtered onto the Ti-Tungsten alloy in the same vacuum pump down during processing, such that any delay that might otherwise be caused by allowing a return to atmosphere is avoided. The Ti-Tungsten layer adheres to the silicon and/or oxide on which it is sputtered. And it prevents the gold layer from reaching the silicon or oxide layer. Other metal systems may also be used in forming metal layers such as layer 2217. For example, in a device having a glass bottom layer, a Tantalum-Platinum layer or a Tantalum-Platinum layer followed by a gold layer may be deposited to form metal layer 2217.

In one embodiment, a Titanium-Tungsten layer that is approximately 1500 angstroms thick is co-sputtered using a sputtering target composed of an alloy having a 1 to 9 ratio of the two elements. Following deposition of the Titanium-Tungsten layer, a layer of gold is sputtered onto the device, preferably in the same vacuum chamber and using the same vacuum pump down. By maintaining the Titanium and Tungsten in a vacuum, exposure to atmosphere and the attendant oxidation is avoided. Avoiding the oxidation is important, because following the deposition of Titanium and Tungsten, a gold layer is deposited. And gold will not properly adhere to an oxidized surface. It is preferable to sputter approximately 5000 Angstroms of gold onto the Titanium-Tungsten layer in this embodiment. A person of skill will recognize that it is possible to have a significant amount of deviation from the preferred thicknesses of the identified layers without deviating from the scope of the invention. One of ordinary skill in the art will recognize that soldering a device with a gold layer as described in the paragraph will often result in the solder dissipating a significant amount of gold. It will also result in a significant amount of gold moving into the barrier layer of Tungsten. Thus, adjustment of the process steps may be needed to ensure that enough gold remains for the desired eutectic solder process.

It has been observed that deposits sputtered from a Titanium-Tungsten alloy target do not adhere as well to an oxide as does a layer comprising solely Titanium. Thus, in some devices, it will be desirable to initially deposit a layer of Titanium using sputter deposition, followed by deposition of a layer of Tungsten by sputter deposition, upon which a layer of gold is deposited by sputter deposition. Depositing the layers in this three-step process has been observed to result in better adhesion between the metal layer and the substrate. Preferably, the adhesion layer (in this embodiment, Titanium) is less than 500 Angstroms thick. The barrier layer (in this embodiment, Tungsten) should be relatively thick compared to the adhesion layer. Thus, it is preferable that barrier layers be approximately 1500 Angstroms thick. The final metal layer (in this embodiment, gold) may be deposited to a thickness of approximately 5000 Angstroms. It is also possible to form the triple metal layer by first sputtering titanium, followed by a barrier layer comprising Titanium and Tungsten, and finally a layer of gold.

It is preferable, but not required, that all three layers be deposited in the same vacuum pump down because, for example, allowing atmosphere to enter will not only cause an undesirable delay in processing, but it may also cause oxidation or other contamination that would require the addition of cleaning steps. In this triple metal layer, titanium forms an adhesion layer and promotes stronger adhesion of the metals to the silicon or oxide. The tungsten is included to provide a barrier layer between the titanium and gold to prevent the gold from reaching the titanium, silicon or oxide and thereby disrupting adhesion. And the gold is provided for connection to the solder.

Further metal combinations may also be used, including Titanium, nickel and gold in a triple layer system that is similar to the above-identified triple layer system except that nickel rather than tungsten provides the barrier layer. A dual chrome and gold layer may also be used in certain devices. However, it is known that chrome-gold metal layers do not provide the same high level of adhesion that is provided by other combinations that are disclosed herein. Yet another acceptable metal layer system is obtained using a triple layer structure of Titanium, Niobium and Gold. It is anticipated that additional metal layer systems will fall within the scope of the disclosed embodiments of pressure sensors, and this invention is not necessarily limited to the metals disclosed herein.

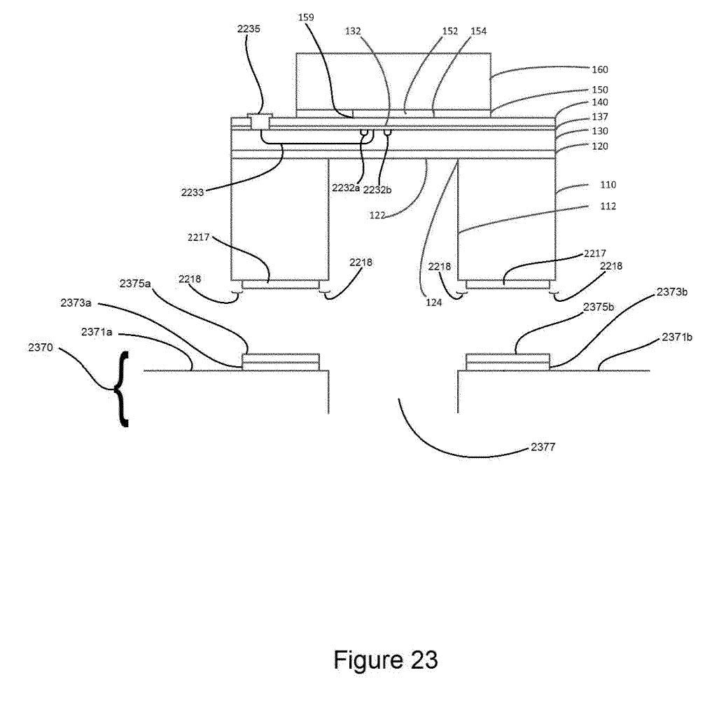

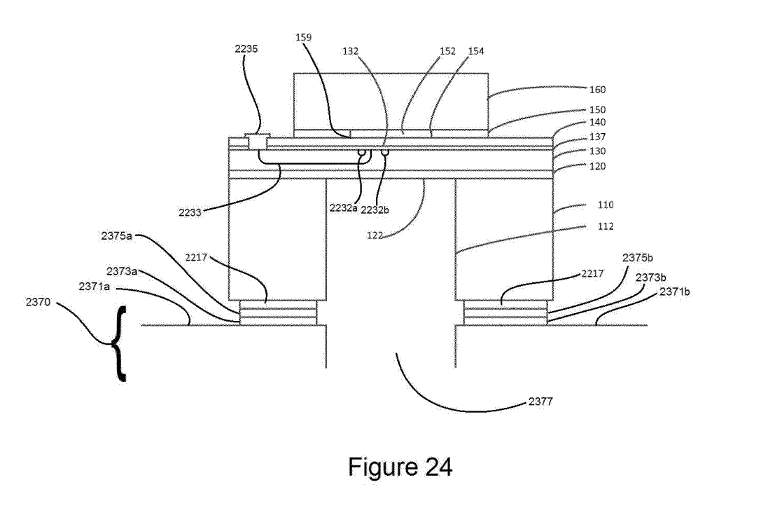

Referring again to FIGS. 23 and 24, a Kovar substrate 2371a, 2371b is provided, having a port 2377 that generally matches the outline profile of cavity 114. The Kovar substrate 2371a, 2371b may be topped with a thin layer of gold prior to formation of the solder structures so that, when soldered to metal layer 117 or 2217, the solder forms a gold-to-gold connection for better conduction of electrical signals. It is believed that Kovar is a trademarked product of CRS Holdings, Inc. comprising a nickel-cobalt ferrous alloy designed to be compatible with the thermal expansion characteristics of borosilicate glass to allow direct mechanical connections over a range of temperatures. Kovar substrate 2371a, 2371b is part of a machined header with a hole (or port) 2377 extending through it, which is relatively large when compared with the pressure sensors disclosed herein.

In FIGS. 22, 23 and 24, it can be seen that metal layer 2217 is recessed from the outer edge of the backside cavity and 114 and the outer edges of the sensor by the width of a recess 2218. Inner and outer recesses 2218 may be the same or different widths, and may be fully or only partially evenly distributed with respect to the edges. It is preferable to form the metal layer with a recess width that is greater than or equal to 1 μm and less than or equal to 20 μm.

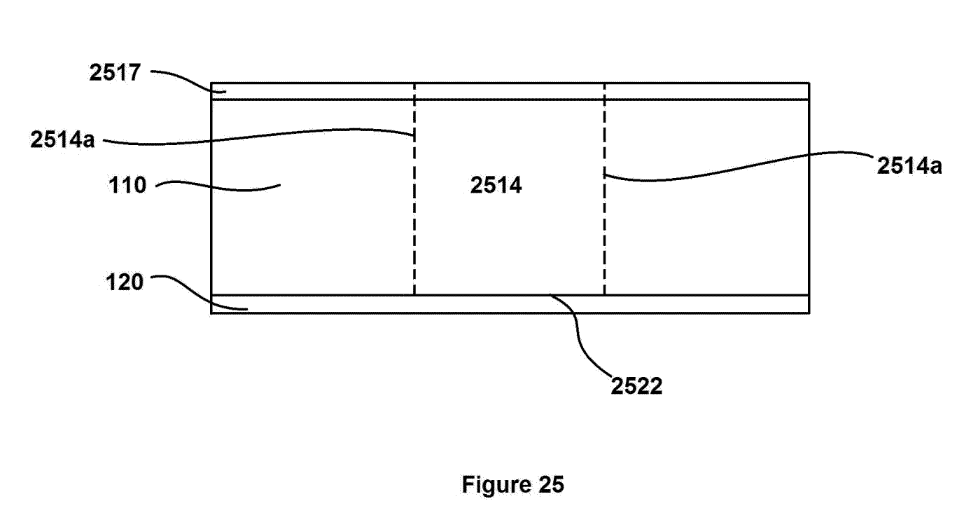

Referring to FIGS. 25-29, the figures show a side of a structure that is being processed to form one of the devices disclosed herein. These figures do not show the entire device, and are inverted with respect to FIG. 1. Accordingly, oxide layer 120 and handle wafer 110 may be the same layers as those indicated in FIG. 1, except in inverted relationship to one another. In a first series of steps, a metal layer 2517 is sputtered on the flat, top surface of wafer 110. The metal layer completely covers the top of the relevant portions of wafer 110. The metal may be deposited by the processes disclosed above. As illustrated in FIG. 25, cavity 114 has not yet been formed in wafer 110. The volume where cavity 114 will be formed is indicated as volume 2514, bounded on the sides and bottom by dashed lines 2514a (indicating the expected future locations of the sidewalls of cavity 114) and interface 2522 indicating the interface between wafer 110 and oxide layer 120.

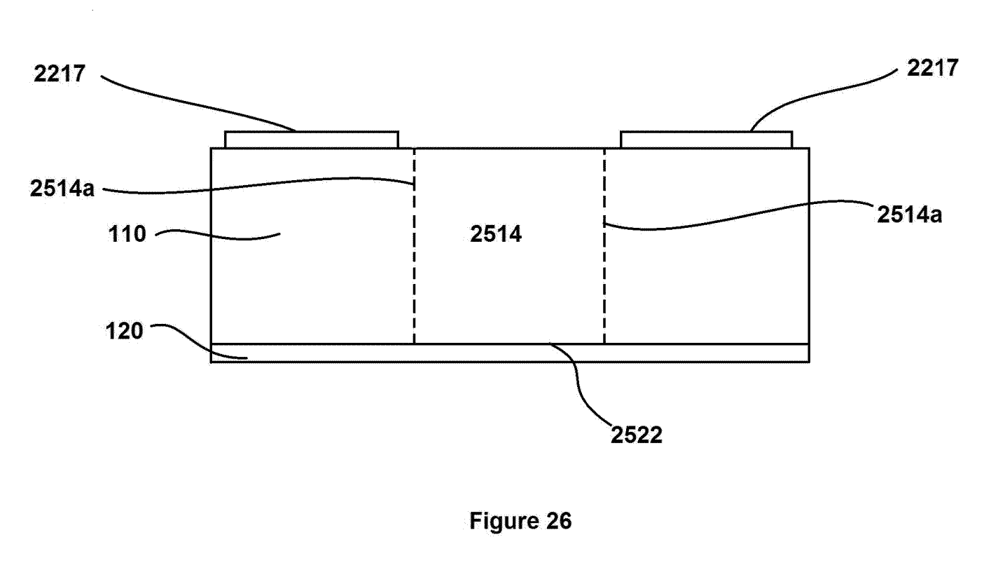

FIG. 26 show the same structure after deposited metal layer 2517 has been patterned into metal layer 2217 by known patterning processes such as photolithography. Although only a cut-away view is available in FIG. 26, it should be understood that metal layer 2217 is preferably patterned to form a continuous path all the way around the top of volume 2514 (which indicates the expected future location of cavity 114) such that it will be possible to form an unbroken solder seal with layer 2375a, 2375b if the sensor is soldered to a substrate such as substrate 2370. Forming an unbroken seal is not always required, but is preferable in most circumstances.

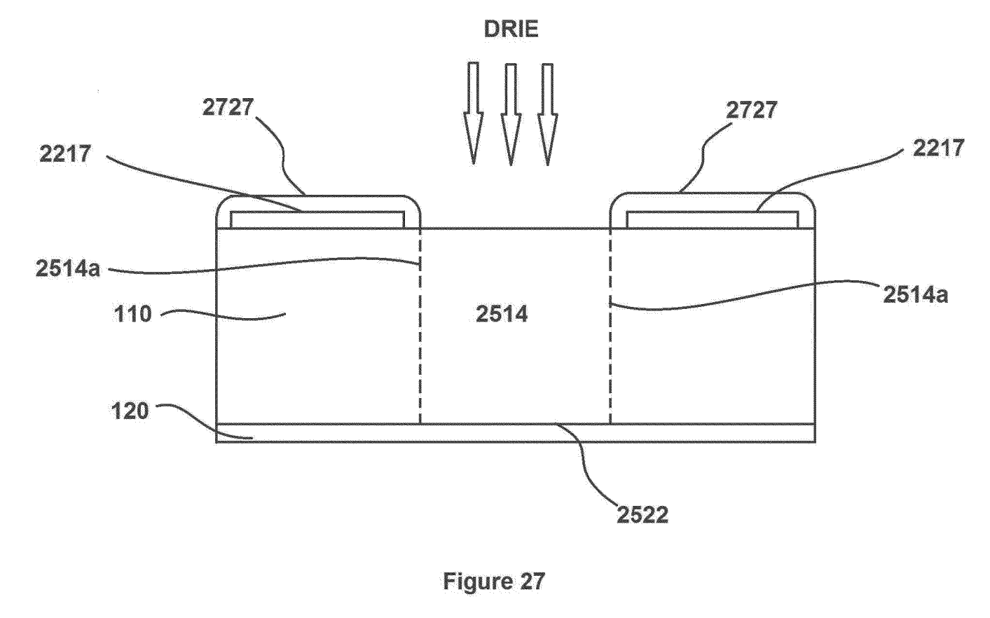

FIG. 27 shows the result of forming a passivation layer 2727 covering metal layer 2217. In the preferred embodiment, passivation layer 2727 is a photoresist layer covering a metal layer 2217 that comprises gold. The passivation layer 2727 is formed in a manner that causes it to extend beyond the edges of metal layer 2217 and to define the boundary of the surface of wafer 110 above volume 2514. This boundary is indicated where dashed line 2514a meets passivation layer 2727.

Following the application of passivation layer 2727, deep reactive ion etching (“DRIE”) is employed (as indicated on FIG. 27) to form cavity 114 in volume 2514. It is preferable to perform the DRIE step after the photolithography step to improve the results of the photolithography which would otherwise suffer if performed after DRIE had perforated the wafer with multiple cavities. Similarly, the application of the passivation layer 2727 is intended to avoid any exposure of gold or other metal in the DRIE cavity. Thus, it is highly preferable to both pattern metal layer 2217 and apply passivation layer 2727 prior to beginning the DRIE process. If the metal layer 2217 is not properly enclosed, portions of the metal will be stripped off of the surface in the plasma formed during the DRIE process. This metal, e.g. gold, is a contaminant in many processes, and may result in undesirable effects if it is dispersed into the DRIE plasma. The DRIE process is performed long enough to extend cavity 114 from the top of wafer 110, completely through the wafer 110 to oxide layer 120, thereby exposing surface 122 of the sensing membrane.

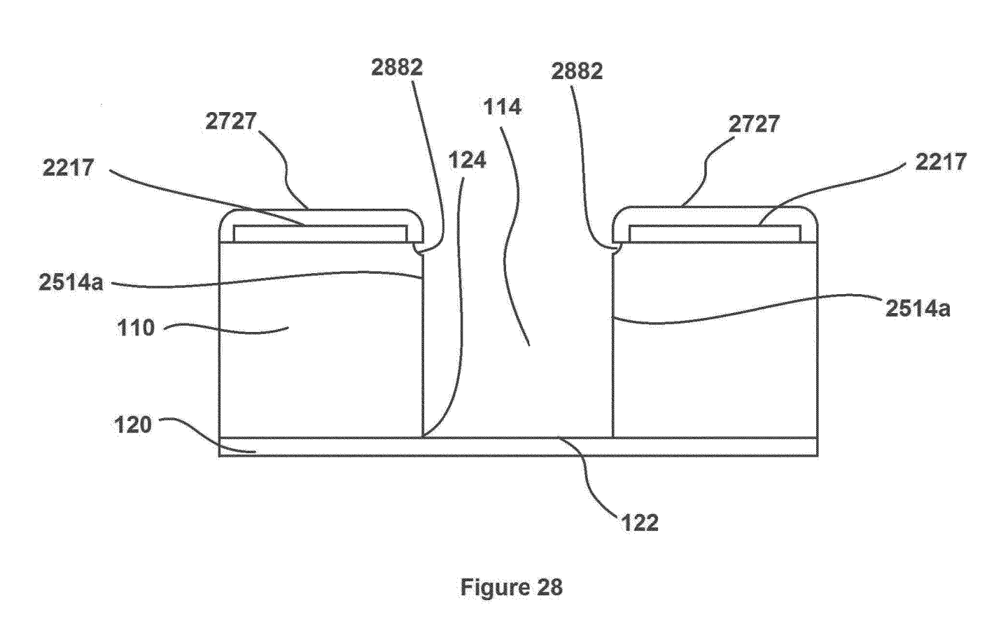

As indicated in FIG. 28, the DRIE process will form relatively small scallops 2882 at the interface of passivation layer 2727 and wafer 110. The scallops extend horizontally into the volume of wafer 110 such that a small portion of the passivation layer 2727 is undercut. The width of recess 2218 may be appropriately sized for any specific DRIE process to prevent the scallops 2882 from undercutting the passivation layer 2727 to such a horizontal distance that the scallop exposes metal layer 2217. In the process described herein, it is desirable to form a recess with a width between 1 μm and 20 μm, with a preference for a value close to 15 μm. A larger recess width may be used, but increased recess size begins to become a less efficient use of wafer space. Using a recess width as described, it is possible to avoid undesirable exposure of metal layer 2727 even if the wafer experiences one or more cumulative shifts of a couple microns in alignment while processing. Whereas, if the recess width was less than 1 μm, a shift of 1 μm during processing would result in exposed gold on at least one edge of cavity 114 during the DRIE process.

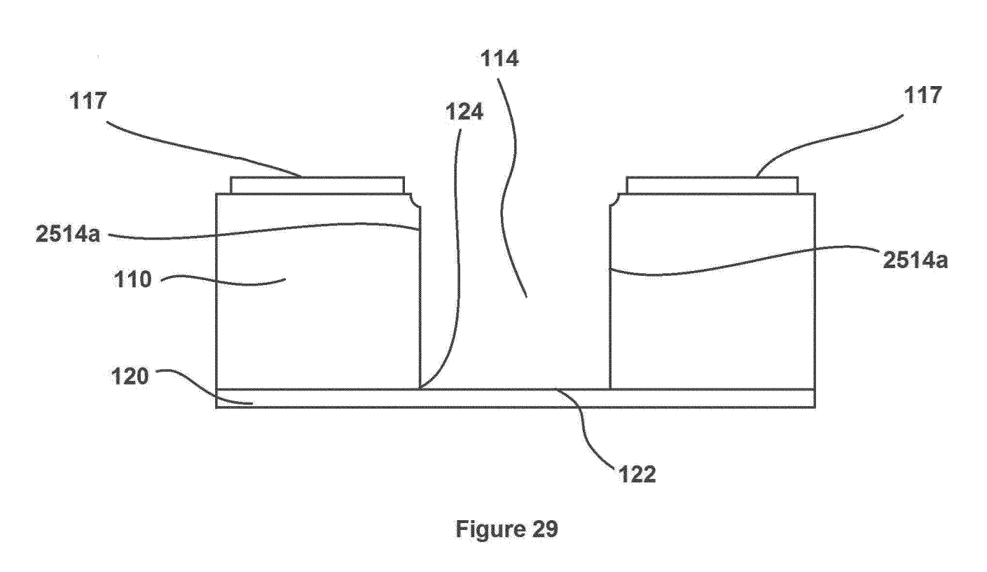

Referring to FIG. 29, after the DRIE process is completed, passivation layer 2727 is removed from metal layer 2217, resulting in metal layer 117, as described in the foregoing portion of this disclosure.

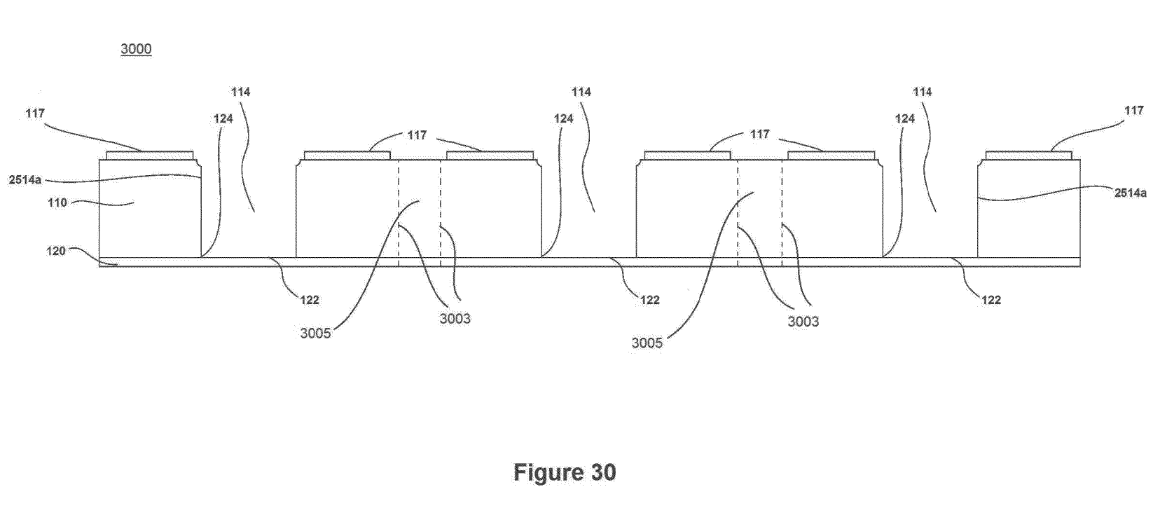

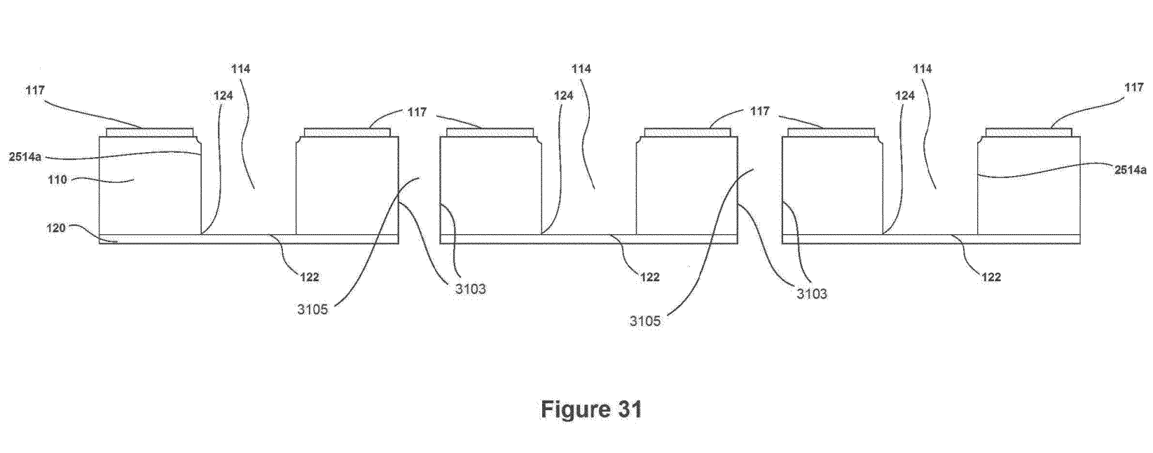

FIG. 30 shows a larger portion of a wafer illustrating three instances of the structure illustrated in FIG. 29, wherein the three structures have not yet been separated, for example by a dicing saw. The volumes indicated as volume 3005 and bounded on the left and right by dashed lines 3003 indicate the material expected to be removed by a dicing saw when the wafer is diced. FIG. 31 shows the same wafer having been diced and with an empty volume 3105 bounded by vertical walls 3103 of adjacent dice. It is notable that a recess corresponding to the outer recesses 2218 is present between wall 3103 and metal layer 117 on each of the illustrated dice. This recess is important, because formation of metal layer 117 too close to wall 3103 may result in smearing or spreading of metal from metal layer 117 along wall 3103 by the dicing saw as the structures are diced. In this instance, device layer 130 is not illustrated below oxide layer 120. However, it will be recognized by persons of ordinary skill in the art that dicing is unlikely to occur prior to the fabrication of a complete sensor. Thus, it is plain that FIG. 31 shows a simplified version of several dice and that device layer 130 would most likely be present. With device layer 130 present, smearing or spreading of metal along wall 3103 by the dicing saw may result in such metal forming a short between device layer 130 and handle wafer 110 or metal layer 117. To avoid such shorting, it is desirable to form an outer recess 2218 (as illustrated, e.g., in FIGS. 22 and 23) between metal layer 117 (or 2217) and outer wall 3103 to reduce or eliminate the possibility of such shorting. This recess is preferably formed with a width between 1 μm and 20 μm, with a preference for a value close to the middle of that range.

In this and other embodiments of the present invention, an optional layer 137 of polysilicon or other material may be placed or formed on a top surface of device layer or wafer 110. Optional layer 137 may be located on a top surface of the device layer 130 and under the bonding or oxide layer 140. That is, optional layer 137 may be located between device layer or wafer 130 and bonding or oxide layer 140. Polysilicon layer 137 may provide a field shield to stabilize the electrical performance of the resistors or other components 132 on the top surface of device layer 130. Optional layer 137 has been omitted from the other figures for clarity.

Again, reference cavity 152 may have a width that is narrower than a width of the backside cavity 114 in at least one direction. In this in other embodiments, reference cavity 152 may be sized and aligned such that it fits within the outer boundaries of backside cavity 114. The result may be that the device membrane is defined in size by recess 152 in cap 160, instead of backside cavity 114, as is conventional. An example is shown in the following figure.

Referring to FIGS. 22-24, specific components 132 and exemplary interconnections are illustrated. Lightly doped resistors 2232a and 2232b may be implanted in the bare silicon top surface of wafer layer 130 while that surface is exposed during processing. A metal bonding pad 2235 may be formed outside of and preferably adjacent to the hermetically sealed chamber 152 and cap 160. Known semiconductor processing processes may be used to provide a hole through oxide layer 140 and, if present, optional layer 137, such that a top surface of wafer layer 130 is exposed at the bottom of the hole. This hole may be filled with appropriate electrically conductive material or materials to form a bonding pad 2235 and provide an electrical connection between an external wire or device (not shown) and wafer layer 130. It is preferable to form bonding pad 2235 using a metal or metal alloy and to shape bonding pad 2235 so that the exposed upper surface of pad 2235 is much wider than the hole through which the metal extends to layer 130. The large exposed upper surface allows for more variance or error in bonding electrical wires or other connections while avoiding failure due to an improper bond. Aluminum, aluminum-silicon with 1% silicon, Aluminum-copper-silicon or other standard bonding pad metals may be used to form pad 2235.

A large p+ diffusion 2233 may also be formed in wafer layer 130, encompassing at least the densest portions of resistor 2232a, and extending laterally to come into contact with the bottom of bonding pad 2235 at the surface where bonding pad 2235 interfaces with wafer layer 130 so that an electrical signal may be conveyed in either direction between bonding pad 2235 and resistor 2232a via diffusion 2233. Diffusion 2233 may also be referred to as an electrical connection. A plurality of such electrical connections may be formed between a plurality of bonding pads and a plurality of implanted components 132 or between two or more implanted components 132. Such diffusions are preferably formed by implanting a very heavy dose of an appropriate impurity to reduce the amount of resistance in the electrical connections. In contrast to this, piezo-resistors, such as resistors 2232a or 2232b are much more lightly doped to provide for an appropriate resistance level and stress responsiveness.

In certain devices, it may be preferable to connect resistor 2232a to bonding pad 2235 using a metal layer (not illustrated) between wafer layer 130 and oxide layer 140. However, in the illustrated embodiments, it is often preferably to use the implanted electrical connection 2233 to preserve the seal between cap 160 and the device layers below the cap. Extending a metal connection across the seal may cause adhesion problems and leave the cavity 152 inadequately sealed. In other embodiments, it may be desirable to extend the electrical connection 2233 from resistor 2232a to a region immediately outside of the outer edge of the cap 160 and provide a metal connection (not illustrated) on top of layer 130 from that region to bonding pad 2235, thereby reducing the implanted length of electrical connection 2233. However, the preferred embodiment is that shown in FIG. 22, wherein the amount of metal in the electrical connection 2233 is reduced significantly. Reducing the amount of metal has the benefit of reducing the need to passivate such metal with another layer during processing.

Preferably the implant dosage for the lower resistance electrical connection 2233 will be on the order of 1×10¹⁵ to 1×10¹⁹ atoms per square centimeter. Such a high dosage lowers the resistance for the electrical connectors. In contrast, the resistors will preferably be dosed with a 1×10¹³ to 1×10¹⁵ atoms per square centimeter dosage to enhance the piezo-resistive response. A person of ordinary skill in the art will understand how to vary the dosage according to the specific process being used to fabricate a particular device. A person of ordinary skill will also understand that, generally, after doping, an annealing process is used to impart desirable qualities to the doped material.

When considering an overhead view of a pressure sensor device, it is known that the overhead width of connection 2233 will affect its resistance. In general, widening connection 2233, while remaining in an appropriate scale for a semiconductor device, will reduce its resistance. Similarly, connection 2233 will have lower resistance if the doping is relatively deep, whereas connection 2233 will have increased resistance as the doping becomes shallower. Similarly, as the length of connection 2233 increases, the resistance will be increased.

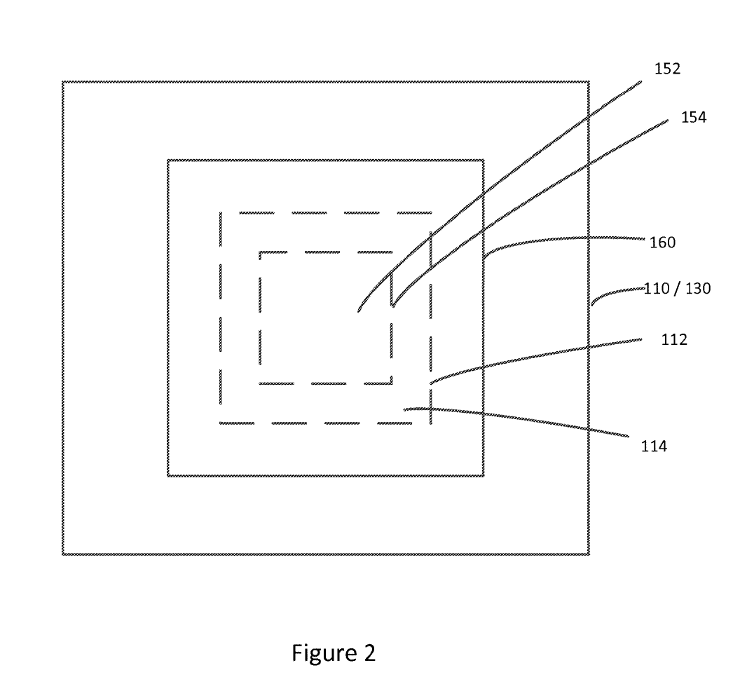

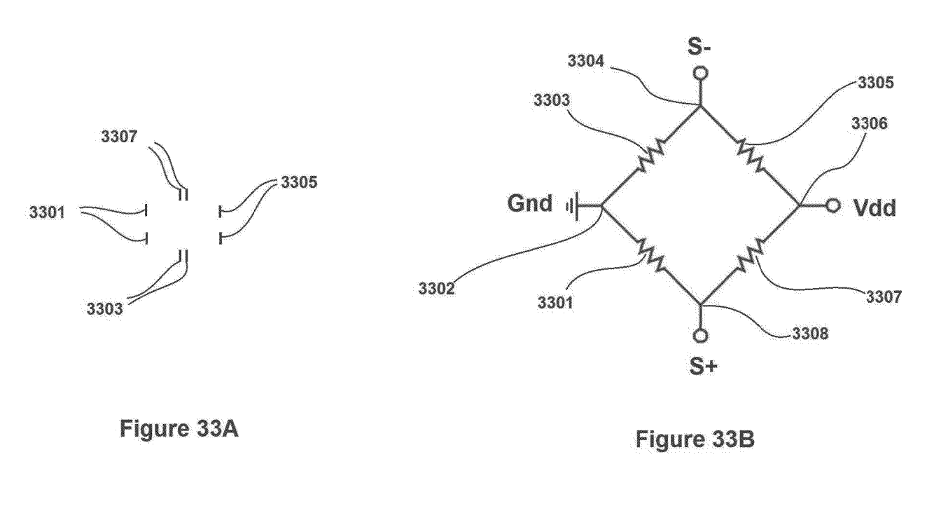

As illustrated in FIG. 33A, which is an overhead view of the piezo-resistors from the same perspective of FIG. 2, sensing piezo-resistors 3301, 3303, 3305, 3307 are relatively very narrow and shallowly doped, so that when all of the resistance in the device is added, the resistance of the piezo-resistors will dominate that of the other traces and the p+ doping. As further illustrated, each of piezo-resistors 3301, 3303, 3305, and 3307, though considered a single resistor schematically, may be formed using two separate, physical resistor structures connected by a lower resistance connection. Each of the piezo-resistor portions preferably has its long direction extending in the same direction in the plane of the wafer. Each of the piezo-resistors is doped with a p− doping and may be formed using the processing steps disclosed with respect to the formation of resistors 2232a, 2232b.

FIG. 33B is a schematic, illustrating the manner in which the piezo-resistors are used to form a Wheatstone bridge. Resistor 3303 is connected between Gnd and S−. Resistor 3301 is connected between Gnd and S+. Resistor 3307 is connected between S+ and Vdd. And resistor 3305 is connected between Vdd and S−. Node 3302 is connected to each of Gnd, resistor 3301 and resistor 3303. Node 3304 is connected to each of resistor 3303, S− and resistor 3305. Node 3306 is connected to each of resistor 3305, Vdd and resistor 3307. And node 3308 is connected to each of resistor 3307, resistor 3301 and S+.

FIG. 33C provides a second schematic illustration that shows generally the doping profile of the various regions corresponding to the schematic of FIG. 33B.

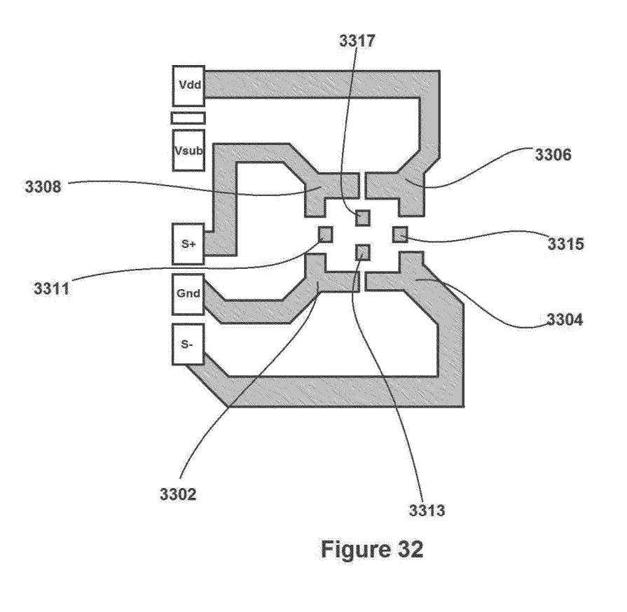

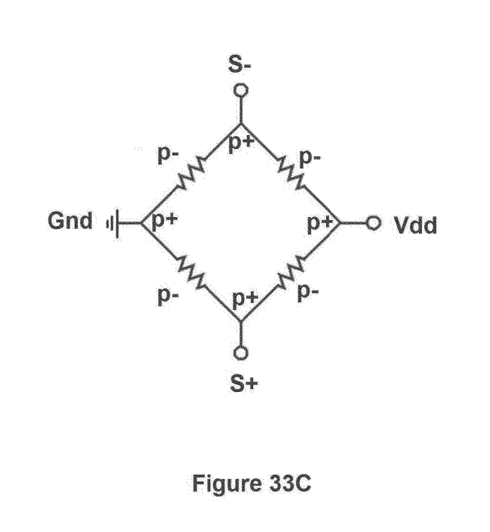

Referring back to FIG. 32—another overhead view of the electrical layout of the device—it can be seen that connection 3311 is provided for connecting the two portions of piezo-resistor 3301. Connection 3317 is provided for connecting the two portions of piezo-resistor 3307. Connection 3315 is provided for connecting the two portions of piezo-resistor 3305. And connection 3313 is provided for connecting the two portions of piezo-resistor 3303. In the illustration of FIG. 32, the resistors are not illustrated for purposes of clarity and to show the individual electrical connections, which will be referred to by the node identifiers used in the schematic of FIG. 33B. Each of nodes/connectors 3302, 3304, 3306, and 3308 is preferably formed to extend generally along and outside of the perimeter of the membrane until the node/connector reaches a point from which it can be extended across a portion of the membrane via a relatively short path. A series of five bonding pads, which may be formed and connected in the same manner as bonding pad 2235, is located along the left-hand portion of the figure. These bonding pads bear labels Vdd, Vsub, S+, Gnd, and S−, which correspond to the similarly labeled nodes in FIG. 33B, except for Vsub. Between nodes Vsub and Vdd, an unlabeled box represents the placement of a temperature sensing diode. Also, each of the shaded areas (labeled 3302, 3304, 3306, 3308, 3311, 3313, 3315 and 3317) represents a region that has been doped as a p+ region to provide an electrically conductive path. Each of the shaded areas of FIG. 32 may be formed using the processing techniques disclosed with respect to electrical connection 2233. Accordingly, which the shaded areas of FIG. 32 may be formed by doping in layer 130, it is also possible to form the shaded portions outside of the perimeter of cap 160 (as illustrated in FIG. 34) using a deposited metal, whereas those portions of the shades areas that are found within the perimeter of cap 160 should be formed using doping rather than a metal trace. When the shaded areas that extend outside of the perimeter of cap 160 are formed using metal, it is desirable to process the doped portion in a manner that extends the doped portion of the shaded areas beyond the perimeter of cap 160 in a manner that will allow an adequate connection beyond the doped volume that forms the portion of the conductive paths farthest from the bonding pads and the metal layer that forms the portion of the conductive paths that connects with the bonding pads. The pattern illustrated in FIGS. 32, 33A and 34 may be altered appropriately and as desired while still staying within the scope of the invention.

FIG. 34 is an overlay of FIGS. 32, 33A and 2 in which several of the numerical identifiers have been omitted for purposes of clarity.

FIG. 2 illustrates a top view of a pressure sensor according to an embodiment of the present invention. Again, cap 160 may be placed on a first wafer portion including handle wafer or layer 110 and device wafer or layer 130. In this example, recess 152 may have edges 154 that are arranged to fit within edges 112 of backside cavity 114. In this example, recess 152 may define the area of the pressure sensor's active membrane. In various embodiments of the present invention, the active membrane may have various sizes. For example, it may be 240 by 240 microns in size. The active membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

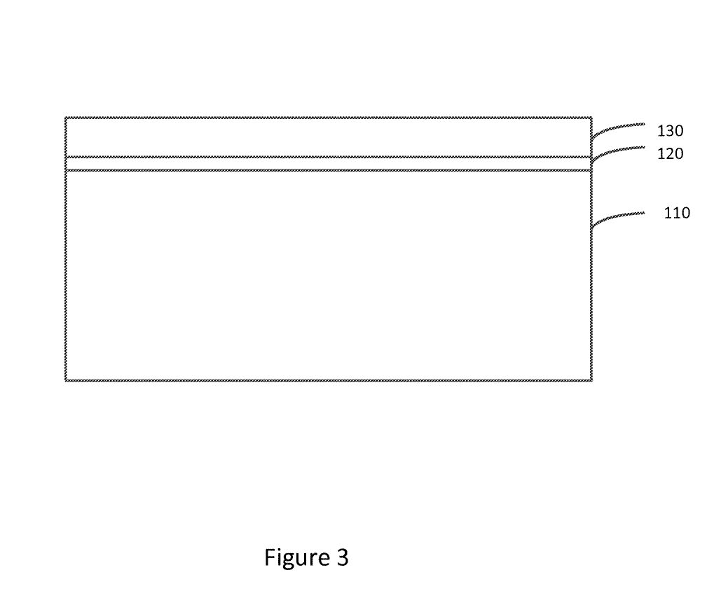

FIG. 3 illustrates a first wafer portion according to an embodiment of the present invention. This wafer portion may include device wafer or layer 130 and handle wafer or layer 110 joined by oxide layer 120 and then thinned. In various embodiments of the present invention, such a structure may be commercially available. In other embodiments of the present invention, oxide layer 120 may be grown on a first wafer 110. A second or device wafer 130 may be fusion bonded to a top side of oxide layer 120. Device wafer 130 may also include an oxide layer, not shown, or oxide layer 120 may be grown on a bottom side device wafer 130. In still other embodiments of the present invention, device layer 130 may be grown as an epitaxial layer on oxide layer 120.

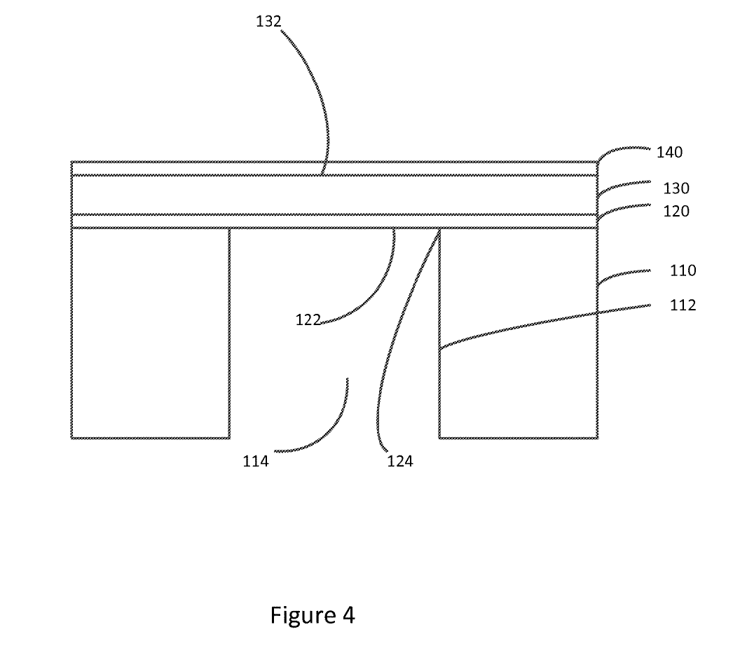

In FIG. 4, backside cavity 114 may be formed. Backside cavity 114 may be formed by etching, for example by using deep reactive-ion etching (DRIE), micromachining, or other technique. Backside cavity 114 may extend from a bottom of handle wafer or layer 110 to a bottom 122 of buried oxide layer 120. One or more electrical components 132 may be placed on, or formed in or on, a top surface of device wafer 130. For example, piezo-resistive resistors may be implanted or diffused in a top surface of device wafer or layer 130. Interconnect traces may be formed on the top surface of device wafer or layer 130. An oxide layer or bonding layer 140 may be grown over device layer 130. This oxide layer 140 may help to protect components 132.

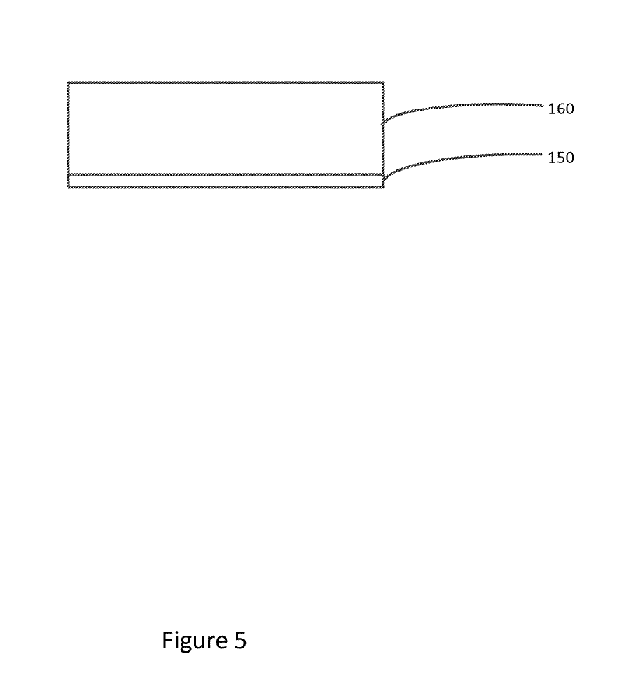

In FIG. 5, cap 160 may be provided. An oxide layer 150 may be grown on a bottom side of cap 160.

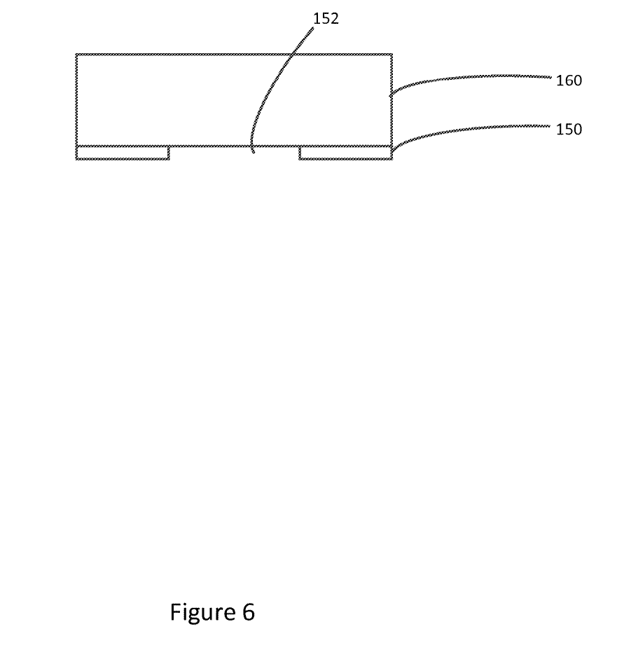

In FIG. 6, an opening 152 may be etched in oxide layer 150 on bottom side of 160. The resulting cap may be attached to the structure in FIG. 4 to produce a pressure sensor shown in FIG. 1.

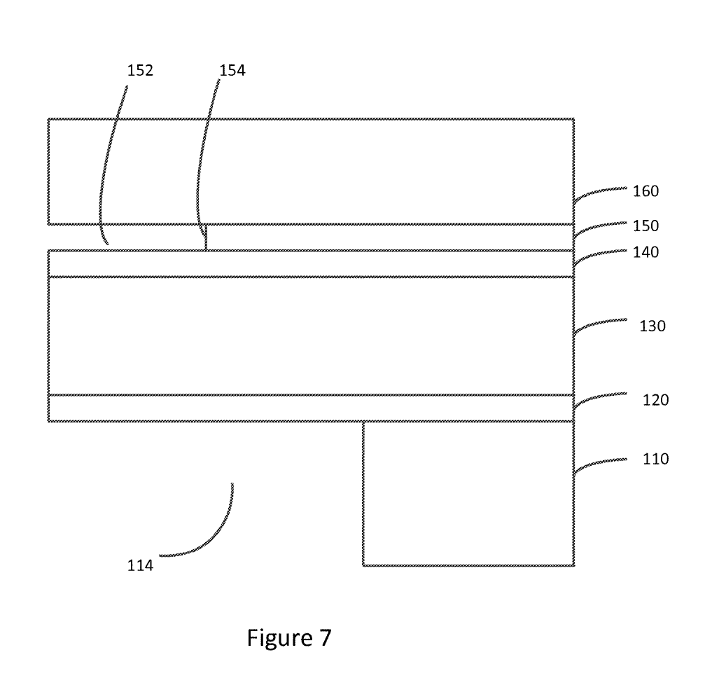

FIG. 7 illustrates a side view of a portion of a pressure sensor according to an embodiment of the present invention. Again, a handle wafer 110 may support a device layer wafer 130. A buried oxide layer 120 may be located between handle wafer portion 110 and device wafer portion 130. Backside cavity 114 may extend from a bottom side of handle wafer 110 to a bottom side 122 of oxide layer 120. Oxide layer 140 may be grown on top of device wafer 130, and an oxide layer 150 may be grown on a bottom side of cap wafer or layer 160, though in various embodiments of the present invention, one or more oxide layers 140 or 150 may be omitted. Oxide layers 140 and 150 may be fusion bonded to join cap 160 to device wafer layer 130. Cap 160 may include recess 152 defined by sidewalls or edges 154. Edges 154 may be flat or have other shapes.

Again, other embodiments of the present invention may provide pressure sensors having a recess that is narrower in at least one direction than a backside cavity. An example is shown in the following figure.

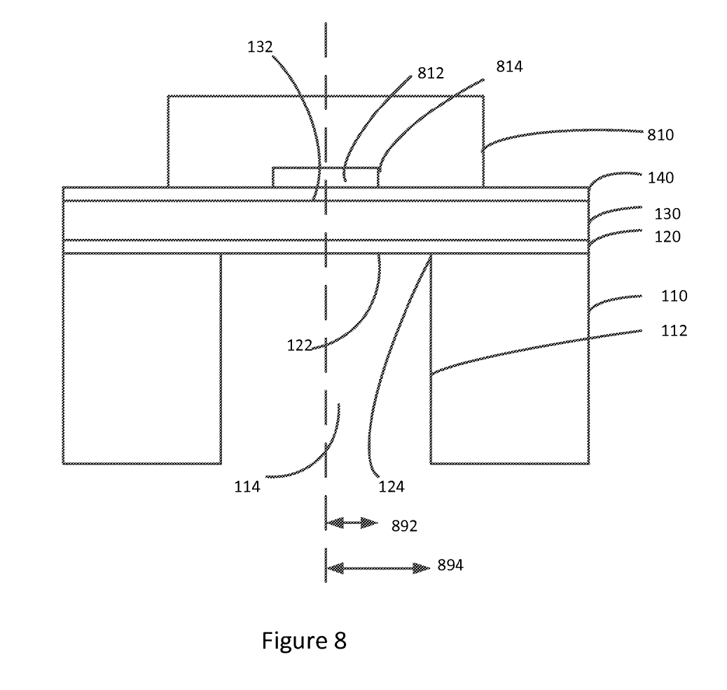

FIG. 8 illustrates a side view of a pressure sensor according to an embodiment of the present invention. In this example, cap 810 may be attached to a top side of device wafer layer 130. Cap 810 may include a recess 812 defining edges 814. Recess 812 may have a width that is narrower in a first direction than a width of backside cavity 114 in the same direction. That is, a distance 892 from a center line of the pressure sensor to an outside edge 814 of recess 812 may be shorter than a distance from the center line to an edge 112 of backside cavity 114. In this and other embodiments of the present invention, edges 814 may be arranged such that they fit within edge 112 of backside cavity 114, again, from a vertical point of view. Also, while in this example, recess 812 may be formed in cap 810, in other embodiments of the present invention, recess 812 may be formed in cap 810, oxide layer 140, device layer 130, or any combination thereof.

As before, various techniques may be utilized to manufacture these pressure sensors. Similar steps to those shown in FIGS. 3 through FIG. 6 may be utilized to form handle wafer or layer 110, oxide layer 120, device layer or wafer 130, and oxide layer 140. Examples of how cap 810 may be formed are shown in the following figures.

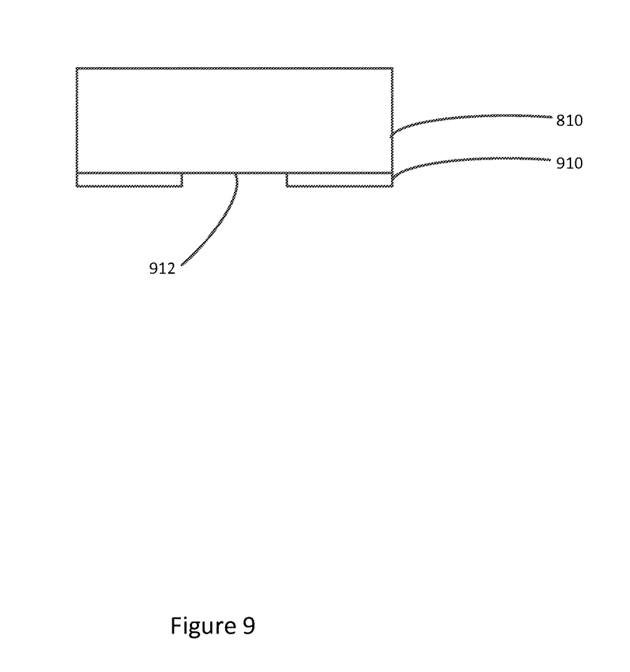

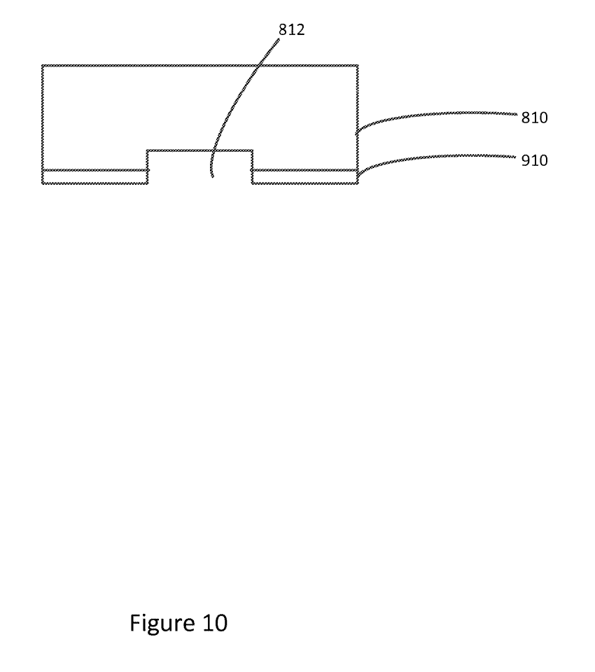

In FIG. 9, a layer of silicon nitride 910 may be deposited on a bottom side of cap 810. An opening 912 may be formed in the silicon nitride layer 910. An oxide layer may then be grown. This oxide layer may have limited growth on a silicon nitride 910, but may consume silicon not protected and exposed by opening 912. This oxide may be removed in FIG. 10 to form recess 812. The silicon nitride layer 910 may also be removed, and there the resulting cap 810 may be fusion bonded to oxide layer 140 on the top of device wafer layer 130 to form the pressure sensor shown in FIG. 8. In other embodiments of the present invention, oxide layer 140 may be omitted, and cap 810 may be bonded to device layer 130.

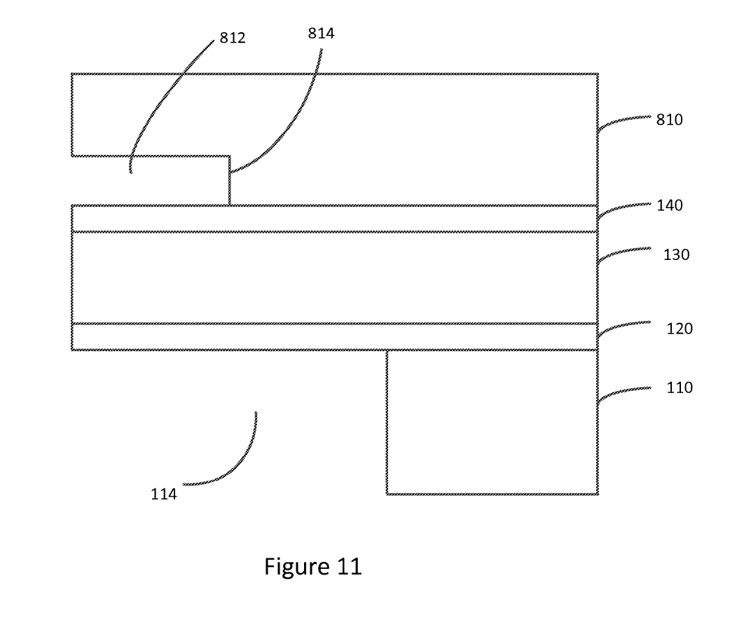

FIG. 11 illustrates a side view of a portion of a pressure sensor according to an embodiment of the present invention. As before, handle wafer or layer 110 may be used to support device wafer or layer 130. Handle wafer 110 may have a backside cavity 114 extending from a bottom of handle wafer or layer 110 to a bottom side of oxide layer 120. An oxide layer 140 may be grown on top of device wafer 130. Cap 810 may be fusion bonded to oxide layer 140. Specifically, silicon on a bottom side of cap 810 may be fusion bonded to oxide layer 140, which may have been grown on device wafer or layer 130. Again, recess 812 may be defined by edges 814. Edges 814 may be flat as shown or have other shapes.

Again, edges 814 of cavity 812 may have other shapes. An example is shown in the following figure.

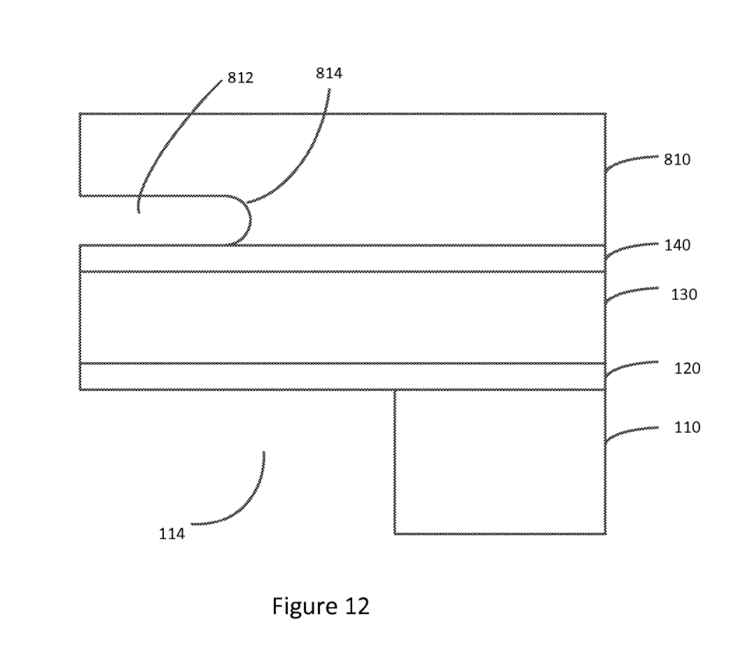

FIG. 12 illustrates an example where an edge 814 of cavity 812 may be curved. This curvature may be caused by the unidirectional consumption of silicon in cap 810 when an oxide layer is grown on a bottom side of cap 810.

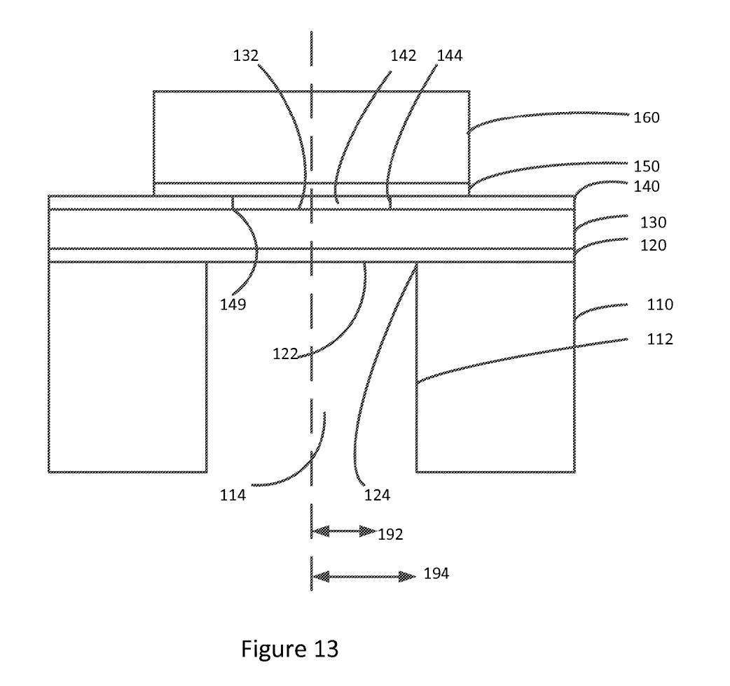

FIG. 13 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 13 0 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though in this and other embodiments of the present invention, oxide layer 150 may be omitted. Cap 160 may be attached to device layer 130 by fusion bonding oxide layer 150 to oxide layer 140. Where oxide layer 150 is not used, cap 160 may be fusion bonded directly to oxide layer 140. Oxide layer 140 may be etched before fusion bonding to form a recess, which is reference cavity 142. Etching oxide layer 140, or other oxide layer, provides an advantage in that oxide etching is traditionally a very well-controlled process step. Also, the thickness of the reference cavity may be precisely controlled by the thickness of the thermal oxide layer 140, which is also a very well controlled process. Reference cavity 142 may be defined by outer edge 144. While in this example reference cavity is shown as extending through oxide layer 140, in various embodiments of the present invention, reference cavity 142 may extend only part way through oxide layer 140. As compared to forming a reference cavity in the cap 160 (as shown in FIG. 1), forming the reference cavity in the oxide layer 140 may simplify the alignment of cap 160 to the membrane. This may be at least partly due to the fact that cap 160 is only used to cover the reference cavity and does not itself define the reference cavity or active membrane. Also, while reference cavity 142 may be formed in oxide layer 140, in other embodiments of the present invention, reference cavity 142 may be formed in oxide layer 140, oxide layer 150, oxide layer 140, cap 160, or any combination thereof.

Reference cavity 142 may have a width that is narrower than a width of backside cavity 114 in at least one direction. Specifically, a distance 192 from a center line of the pressure sensor to an edge 144 of reference cavity 142 may be shorter than a distance 194 from a center line to an edge 112 of backside cavity 114. In this way, an active portion of a membrane defined by edge 144 may be narrower than the active membrane defined by edge 112.

In conventional pressure sensors, cap 160 may be absent, or cap 160 may have a recess that forms an opening that is wider than a corresponding backside cavity. In such case, as a membrane or diaphragm formed by a backside cavity deflects, a junction point between a diaphragm and frame may experience a large tensile force. In this figure, if cap 160 were absent, this force would be concentrated at location 124. This concentration of force may result in cracks or other damage at or near location 124.

Accordingly, as described above, embodiments of the present invention may provide a cap or other reinforcing structure, such as cap 160, where a reference cavity, such as reference cavity 142, may be narrower than a backside cavity, such as backside cavity 114. In this case, location 124 may be reinforced by cap 160. Also, the location of highest stress moves from the location 124 to location 149. The stress at location 149 is compressive when pressure is applied to the underside of membrane 122, rather than tensile. Further, even when one or more cracks or other damage appears at or near location 124, the cracks are away from the membrane area, which is defined by reference cavity 142.

Also, in conventional pressure sensors, a membrane or diaphragm may deflect an amount that may cause damage to the pressure sensor. This may occur due to the presence of unforeseen high pressures from fluids in the backside cavity, or by another event.

Accordingly, embodiments of the present invention may provide a reference cavity having height or thickness that limits a maximum deflection of the membrane. In various embodiments of the present invention, this height or thickness may be such that a membrane may be able to deflect enough for desired operation, but not enough to cause damage to the pressure sensor. Specifically, edge 144 may have a height that allows the membrane to deflect enough for proper operation of the pressure sensor, but not enough to cause damage or rupture the membrane. Instead, the membrane deflects such that it reaches a top of the reference cavity 142 and cannot go any further before damage is caused. That is, the top of the reference cavity 142 may act as a deflection stop to prevent damage to the pressure sensor. In this and other embodiments of the present invention, one or more surfaces, such as the top surface of reference cavity 142 may include one or more bosses or other structures that may act as a stop or limit on the amount that an active membrane may deflect.

Again, in various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 142, as with the other reference cavities in other embodiments of the present invention, may have a thickness or height of 100 nm to 500 nm, though in other embodiments may it may be from 50 m to 1000 nm. A specific embodiment of the present invention may have a reference cavity having a height of 4000 A.

Again, reference cavity 142 may have a width that is narrower than a width of the backside cavity 114 in at least one direction. In this in other embodiments, reference cavity 142 may be sized and aligned such that it fits within backside cavity 114. The result is that the device membrane is defined in size by recess 142 in oxide layer 140, instead of backside cavity 114, as is conventional. An example is shown in the following figure.

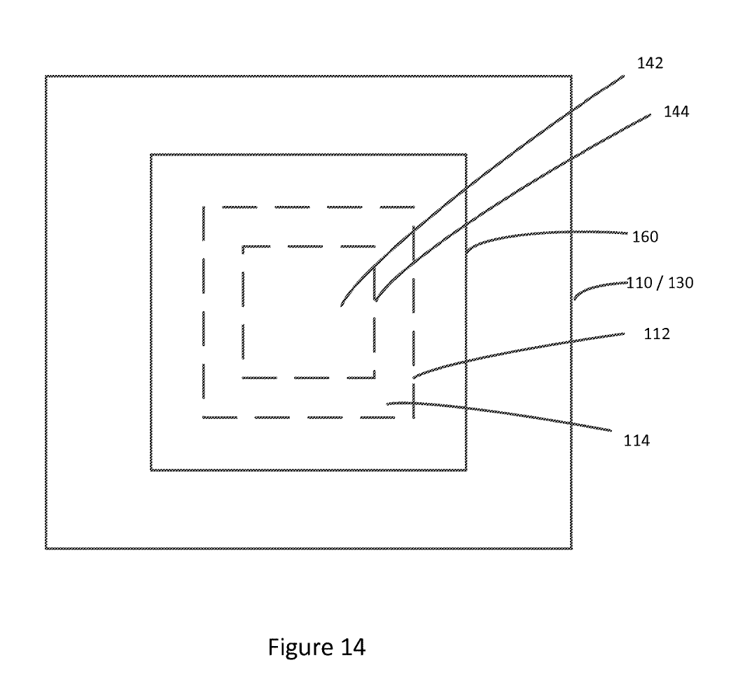

FIG. 14 illustrates a top view of a pressure sensor according to an embodiment of the present invention. Again, cap 160 may be placed on a first wafer portion including handle wafer or layer 110 and device layer or wafer 130. In this example, reference cavity 142 may have edges 144 that are arranged to fit within edges 112 of backside cavity 114. In this example, reference cavity 142 may define the area of the pressure sensor's active membrane. In various embodiments of the present invention, the active membrane may have various sizes. For example, it may be 240 by 240 microns in size. The membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

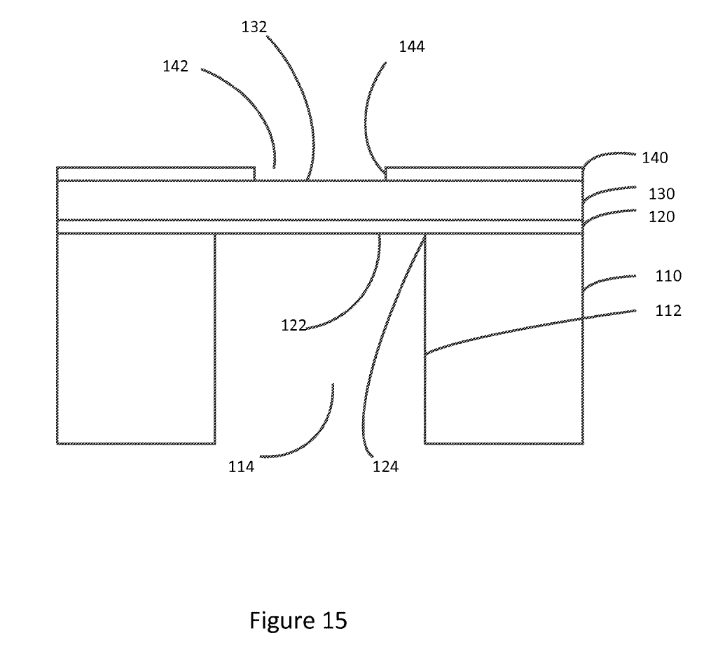

FIG. 15 illustrates a portion of a pressure sensor being manufactured. This portion may be formed in a same or similar manner as the portion shown in FIG. 4. Additionally, a recess may be formed in layer 140 that will form reference cavity 142. Again while the reference cavity 142 is shown as extending through oxide layer 140, in other embodiments of the present invention, reference cavity 142 may extend only partly though oxide layer 140. A cap 160, either with or without oxide layer 150, may be placed over reference cavity 142 to form the pressure sensor of FIG. 13.

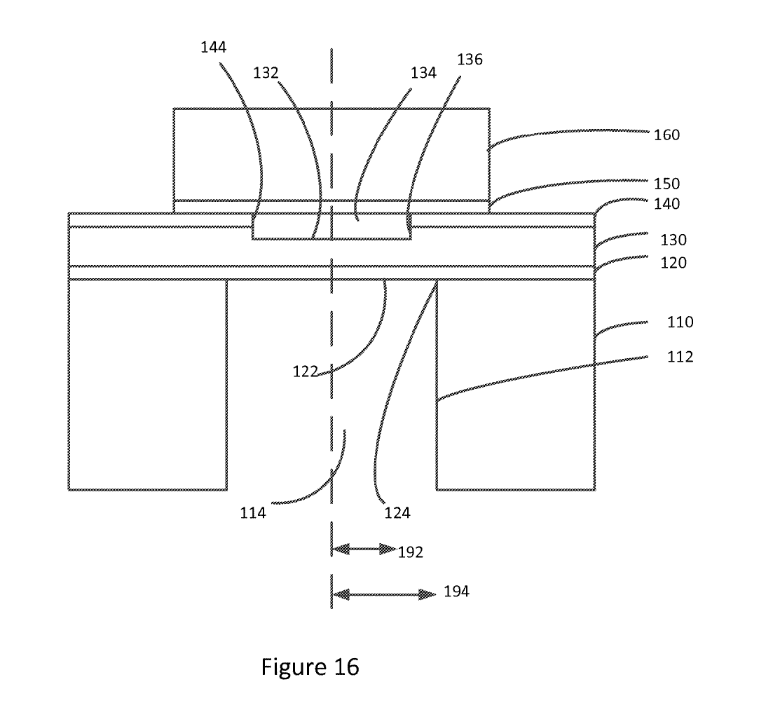

FIG. 16 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 13 0 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in its top surface. Electrical components 132 may be protected by oxide layer 140.

Cap 160 may include oxide layer 150 on a bottom surface, though oxide layer 150 may be omitted in this and other embodiments of the present invention. Cap 160 may be attached to device layer 130 by fusion bonding oxide layer 150 to oxide layer 140. Where oxide layer 150 is not used, cap 160 may be fusion bonded directly to oxide layer 140, or cap 160 may be bonded directly to device layer 130. Oxide layer 140 may be etched before fusion bonding to form a top portion of a recess, which is reference cavity 142. Device layer 130 may also be etched to form a bottom portion of reference cavity 134. Reference cavity 134 may be defined by outer edges 144 and 136. As compared to forming a reference cavity in the cap 160 (as shown in FIG. 1), forming the reference cavity in the oxide layer 140 and device layer 130 may simplify the alignment of cap 160 to the membrane. This may be at least partly due to the fact that cap 160 is only used to cover the reference cavity and does not itself define the reference cavity. Also, while reference cavity 134 is formed in the oxide layer 140 and device layer 130, in other embodiments of the present invention, oxide layer 140 may be omitted and reference cavity 134 may be formed in device layer 130.

Reference cavity 136 may have a width that is narrower than a width of backside cavity 114 in at least one direction. Specifically, a distance 192 from a center line of the pressure sensor to edge 144 and 136 of reference cavity 134 may be shorter than a distance 194 from a center line to an edge 112 of backside cavity 114. In this way, an active portion of a membrane defined by edges 144 and 136 may be narrower than the membrane defined by edge 112.

Also, in conventional pressure sensors, a membrane or diaphragm may deflect an amount that may cause damage to the pressure sensor. This may occur due to the presence of unforeseen high pressures from fluids in the backside cavity, or by another event.

Accordingly, embodiments of the present invention may provide a reference cavity having height or thickness that limits a maximum deflection of the membrane. In various embodiments of the present invention, this height or thickness may be such that a membrane may be able to deflect enough for desired operation, but not enough to cause damage to the pressure sensor. Specifically, edges 136 and 144 may have a height that allows the membrane to deflect enough for proper operation of the pressure sensor, but not enough to cause damage or rupture the membrane. Instead, the membrane deflects such that if it reaches a top of the reference cavity 142 or 134, it cannot go any further before damage is caused. That is, the top of the reference cavity 134 may act as a deflection stop to prevent damage to the pressure sensor. In this and other embodiments of the present invention, one or more surfaces, such as the top surface of reference cavity 134 may include one or more bosses or other structures that may act as a stop or limit on the amount that an active membrane may deflect.

Again, in various embodiments of the present invention, the structures used in pressure sensors may have various sizes and width. For example, handle wafer or portion may have a thickness of 250 to 600 microns, though it may be thinner than 250 or thicker than 600 microns. Device wafer or layer 130 may be considerable thinner since it forms the membrane. This thickness may be 15-25 microns, though it may be thinner than 15 or thicker than 25 microns. The cap wafer or layer 160, and other cap wafer or layers, may have a thickness that is at least approximately 150 microns, though it may be narrower or thicker than 150 microns. The buried or bonding oxide layers 120, 140, and 150 may have a thickness between 0.1 and 3 microns, though they may be thinner or thicker than this range. The reference cavity 134, as with the other reference cavities in other embodiments of the present invention, may have a thickness or height of 100 nm to 500 nm, though in other embodiments may it may be from 50 m to 1000 nm. A specific embodiment of the present invention may have a reference cavity having a height of 4000 A.

Again, reference cavity 134 may have a width that is narrower than a width of the backside cavity 114 in at least one direction. In this in other embodiments, reference cavity 134 may be sized and aligned such that it fits within backside cavity 114. The result is that the device active membrane is defined in size by reference cavity in oxide layer 140 and device layer 130, instead of backside cavity 114, as is conventional. An example is shown in the following figure.

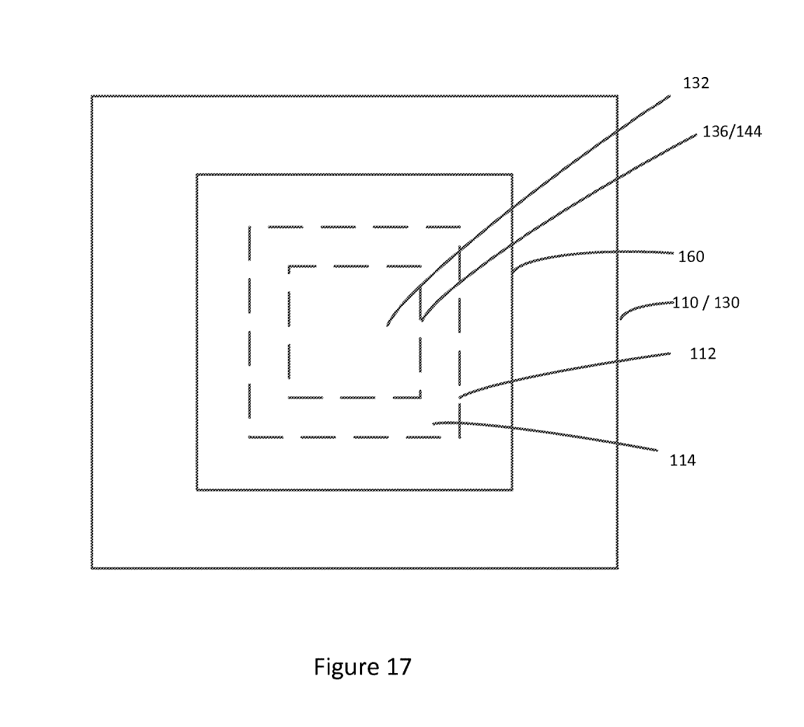

FIG. 17 illustrates a top view of a pressure sensor according to an embodiment of the present invention. Again, cap 160 may be placed on a first wafer portion including handle wafer or layer 110 and device layer 130. In this example, reference cavity 142 may have edges 144 that are arranged to fit within edges 112 of backside cavity 114. In this example, reference cavity 142 may define the area of the pressure sensor's active membrane. In various embodiments of the present invention, the active membrane may have various sizes. For example, it may be 240 by 240 microns in size. The membrane thickness may be on the order of 20 microns. Such a membrane or diaphragm may support and be able to measure pressures up to 20 bar, 120 bar, or more.

The various layers shown here may be omitted, and others may be included consistent with embodiments of the present invention. A specific example of a method of manufacturing an embodiment of the present invention is shown in the following figures.

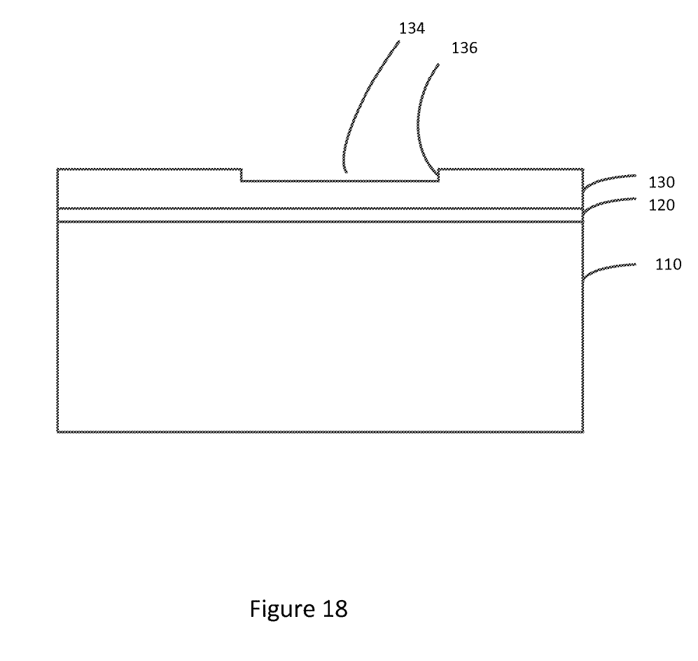

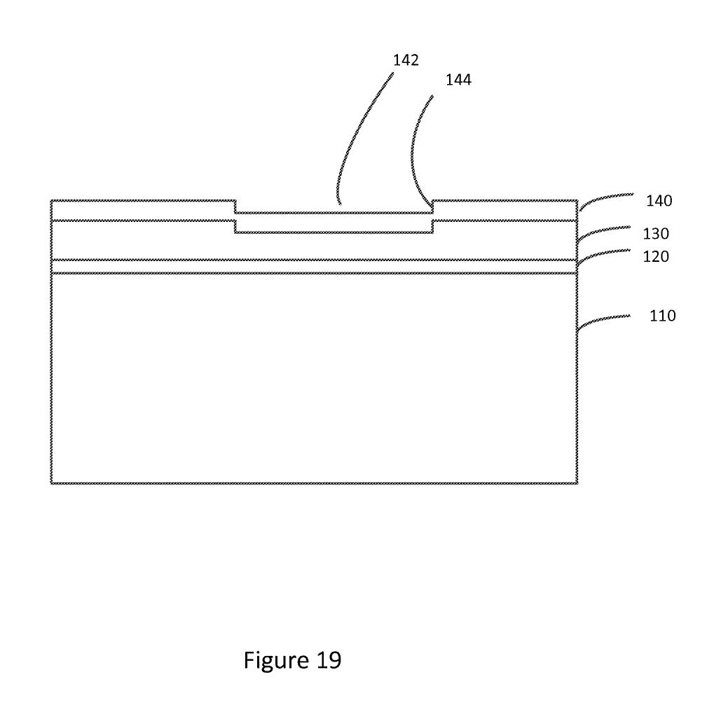

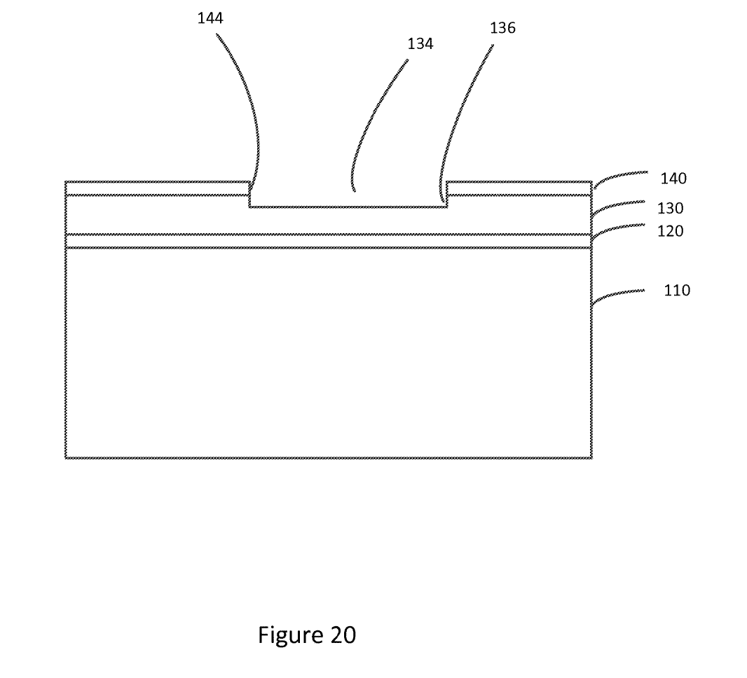

The pressure sensor portion in FIG. 18 may be formed in a same or similar manner as the pressure sensor portion of FIG. 3. Additionally, a recess may be etched in a top of device layer 130 to form a lower portion of reference cavity 134. In FIG. 19, an oxide layer 140 may be formed over device layer 130. This oxide layer may be kept in place to protect devices 132, or oxide layer 140 may be etched to form the reference cavity 134 defined by sides 144 and 136, as shown in FIG. 20.

In other embodiments of the present invention, the pressure sensor portion of FIG. 20 may be formed by growing oxide layer 140 over device layer 130, then etching through oxide layer 140 into the top of the device layer 130 to form reference cavity 134 defined by sides 144 and 136.

In other embodiments of the present invention, the membrane may include structures such as bosses, racetracks, and other structures. Examples may be found in U.S. Pat. No. 8,381,596, which is incorporated by reference. An example is shown in the following figure.

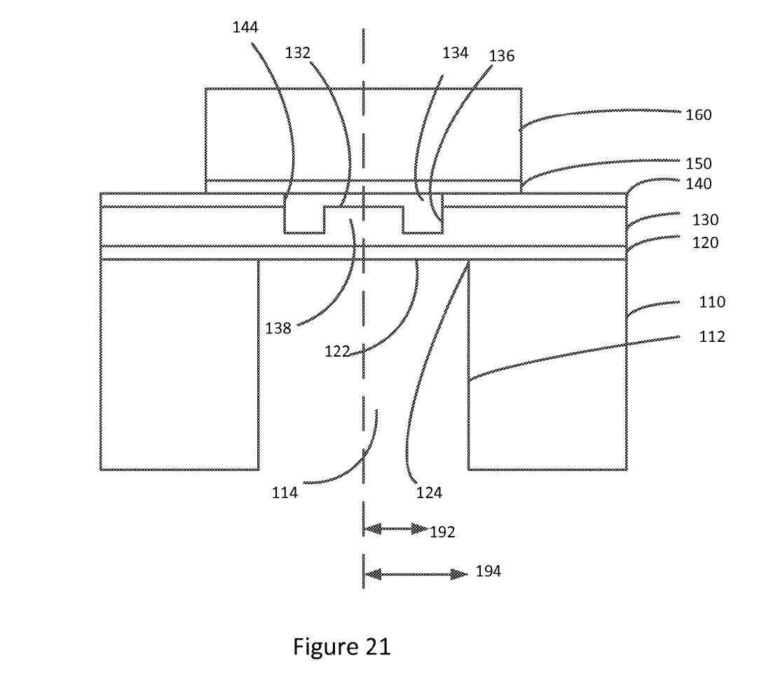

FIG. 21 illustrates a side view of another pressure sensor according to an embodiment of the present invention. As before, this pressure sensor may include cap 160 attached to a top of a first wafer portion that includes device wafer or layer 130 and handle wafer or layer 110. Device wafer of layer 13 0 may be supported by handle wafer or layer 110. Handle wafer or layer 110 may include a backside cavity 114 defining an edge of sidewall 112. Backside cavity 114 may extend from a bottom surface of handle wafer or layer 110 to a bottom 122 of oxide layer 120. Device layer 130 may have one or more electrical components 132 formed in boss 138, where boss 138 is an example structure formed in device layer 130. Electrical components 132 may be protected by oxide layer 140, though this is not shown here for clarity.

Cap 160 may include oxide layer 150 on a bottom surface, though oxide layer 150 may be omitted in this and other embodiments of the present invention. Cap 160 may be attached to device layer 130 by fusion bonding oxide layer 150 to oxide layer 140. Where oxide layer 150 is not used, cap 160 maybe fusion bonded directly to oxide layer 140. Oxide layer 140 maybe etched before fusion bonding to form a top portion of a recess, which is reference cavity 142. Device layer 130 may also be etched to form racetracks, bosses, or other structures that may form a portion of reference cavity 134. These structures may limit a maximum deflection of an active membrane to prevent damage to the device due to the presence of high pressures in backside cavity 114 or other event. Reference cavity 134 may be defined by outer edges 144 and 136. As compared to forming a reference cavity in the cap 160 (as shown in FIG. 1), forming the reference cavity in the oxide layer 140 and device layer 130 may simplify the alignment of cap 160 to the membrane. This may be at least partly due to the fact that cap 160 is only used to cover the reference cavity and does not itself define the reference cavity.

Reference cavity 136 may have a width that is narrower than a width of backside cavity 114 in at least one direction. Specifically, a distance 192 from a center line of the pressure sensor to edge 144 and 136 of reference cavity 134 may be shorter than a distance 194 from a center line to an edge 112 of backside cavity 114. In this way, an active portion of a membrane defined by edges 144 and 136 may be narrower than the membrane defined by edge 112.

As noted above, polysilicon layer 137 may provide a field shield to stabilize the electrical performance of the resistors or other components 132 on the top surface of device layer 130. In many embodiments, however, it is preferable to form an implanted field shield within a top surface of the wafer layer 130, with the conductive traces/connections 2233 below the field shield.

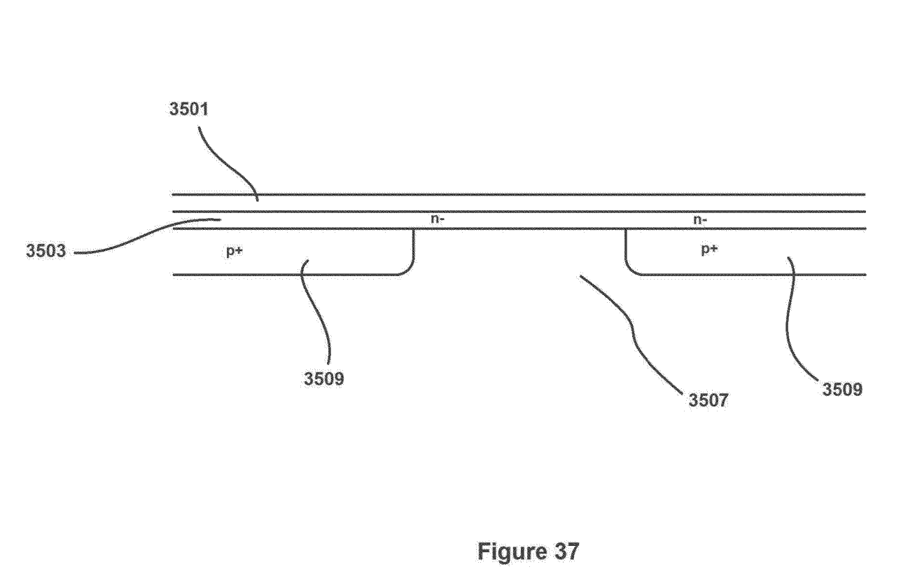

A field shield would ideally surround the sensor devices such as resistors 2232a, 2232b, 3301, 3303, 3305, 3307 with Faraday cage or metal cage that is impenetrable by electrical fields and charges. However, in semiconductor fabrication of the type disclosed herein, it is not now possible to create such cages with metal. However, it is possible to surround the p− regions with n− doped regions that will act as a field shield and reflect or repel undesired charges and/or fields. For example, a positive charge sitting on or above the surface of oxide layer 3501 (indicated, for example, as a circled-plus on FIG. 38) will not be able to penetrate easily to the p− regions 3505, 3509, because any electric field running between the charge and the surface of the layer will interact with the n− region 3503 and not affect the p− regions 3505, 3509.

The implanted field shield disclosed herein provides for advantageous operation of the resistors shielded by the field shield, as they will be less likely to encounter interference from external charges. It will be particularly advantageous to employ the field shield disclosed herein in the formation of pressure sensors that have membranes exposed to the atmosphere and attendant free-floating ions when in use. Such free-floating ions may otherwise affect the resistor(s). Additionally, undesirable surface charges may form along the interface between the oxide layer 3501 and the silicon layer 3507. Such surface charges may change over time; changing of the surface charges may affect the resistor below, unless a barrier such as an implanted field shield is formed between the resistor and the interface.

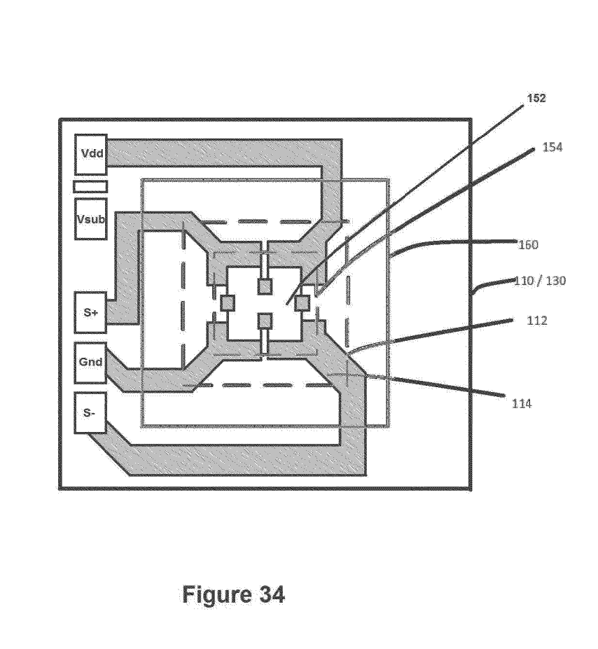

A preferred method of forming such a field shield is now disclosed. Referring now to FIGS. 35-38, a device layer 3507 formed of n-type silicon is provided for the fabrication of devices such as resistors 2232a, 2232b. Device layer 3507 may correspond to wafer layer 130. During processing, a relatively thin oxide layer 3501 is formed on the top surface of device layer 3507. The oxide layer is preferably formed prior to implantation of p-type or n-type dopants, as it is standard practice in the integrated circuit industry to implant through a thin oxide layer. After all of the implants have been accomplished, a single long high-temperature drive in may be performed to diffuse each of the implanted species farther into the silicon layer 130. Additional oxide can also be grown during this drive in to better protect the surface of layer 130. However, since the growth of oxide consumes both silicon and the dopants therein, it will affect the doping profiles of the implanted regions. This effect should be accounted for when planning depths and concentrations of layers 3503, 3505 and 3505. It will be recognized that more flexibility in designing the doping profiles of the n−, p− and n+ species is possible by using multiple drive-ins interspersed between the various implants.

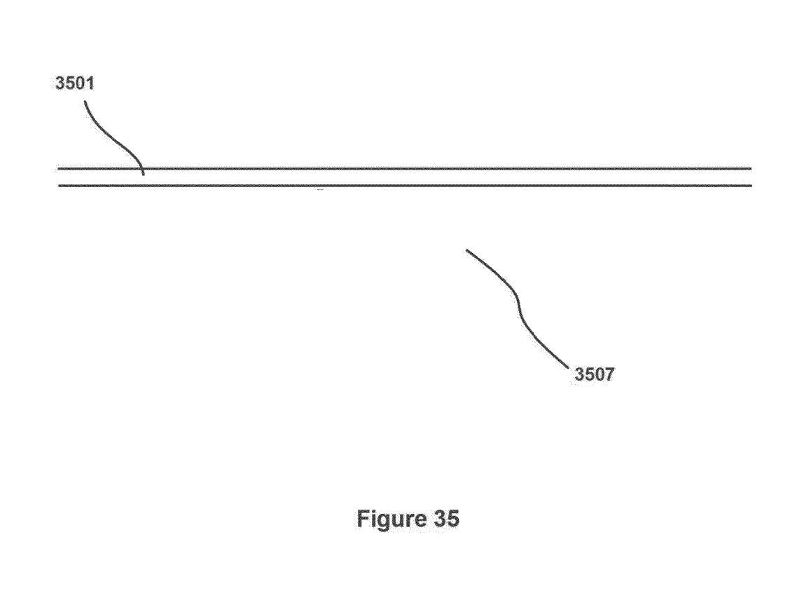

Referring now to FIG. 36, an n− dopant is preferably implanted into the entire surface of the wafer. This implant is used to increase the concentration of n-type dopant above that in the uniform concentration level in layer 3507 in a thin n− region 3503. The n− dopant may be, for example, Arsenic or Phosphorus.

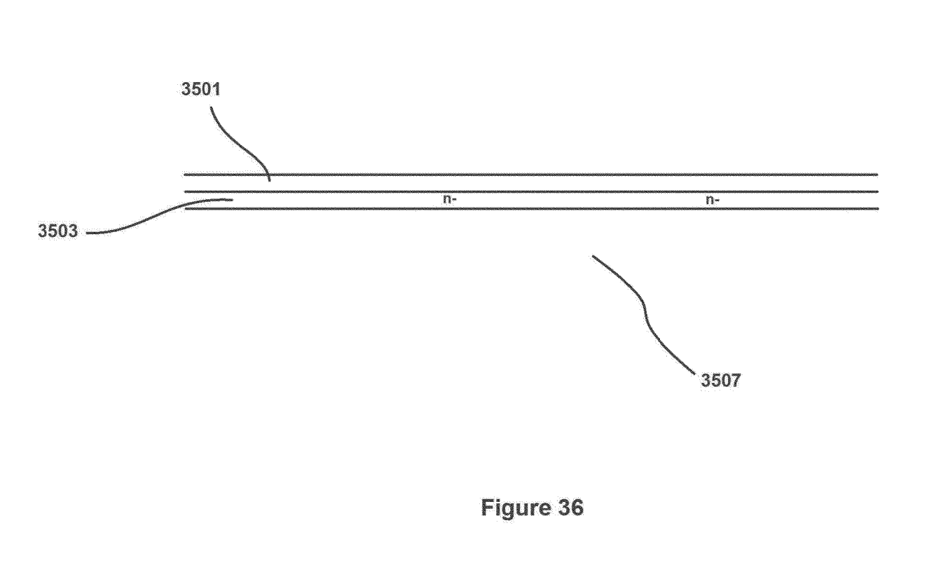

After the n− doping, referring to FIG. 37, a heavy dose of p+ dopant is implanted in specified regions to greater depth than the depth of the n− dopant. The p+ dopant forms p+ regions 3509 in layer 3507. The p+ regions are formed below the n− region 3503. The p+ regions may form, for example connections 2233 and may also correspond to the shaded regions in FIG. 32. The p+ doping is much heavier than the n− doping. Accordingly, even though the n− region 3503 is illustrated as extending across the entire surface of silicon layer 3507 for purposes of clarity, it will be understood that in the regions where the n− region 3503 is above p+ regions 3509, the p+ doping will overwhelm the n− doping, and that area will be p-type. Due to this property of the heavy p+ doping, it is possible to save cost and process time by avoiding any need to pattern the n− doping. Instead, the n− doping can be performed over the entire surface of silicon layer 3507. This is due to the understanding that the p+ region has significantly low resistance that it will not be affected significantly by external fields or charges, whereas the resistor is lightly doped and resistance may change noticeably due to an external charge or field. Specifically, one charge may have far more effect on carriers that are flowing through the lightly doped region.

It is preferable to implant a p− dopant following the p+ doping. Referring to FIG. 38, the p− dopant is implanted deeper than the n− dopant, but to a shallower depth in layer 3507 than is the p+ dopant. The p− dopant forms a shallow, doped region 3505, connecting regions 3509. The p− dopant is implanted deeper than the n− region 3503. The p− region may be used to form piezo-resistors 3301, 3303, 3305, and 3307, as illustrated in FIGS. 33A and 34 and devices 2232a, 2232b. Because the p− doping is a lighter dosage than the n− doping, even though p− ions are present in portions of n− region 3503, the heavier n− doping will overwhelm the effect of the p− doping and the region 3503 will remain an n− region above the p− region 3505.

In another process embodied by the invention disclosed herein, the n− layer 3503 may be implanted after the p− and/or p+ dopants with appropriate modification of the process flow, times and temperatures to ensure that the n− layer 3503 remains above the p− and p+ regions 3505, 3509. In other words, regardless of the order of implantation, it is important that the n− dopant is not driven as deeply into silicon layer 3507 as are the p− and p+ dopants.

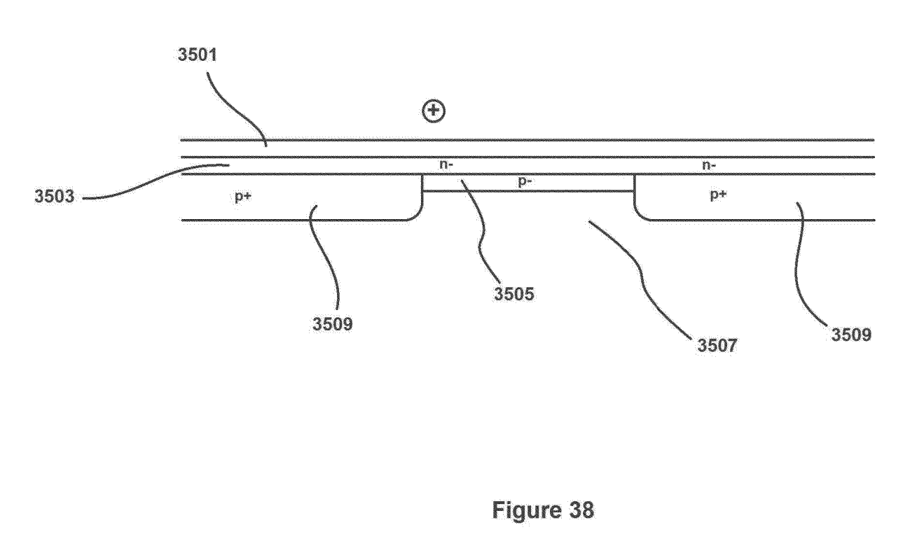

As noted above, with respect to FIG. 34, a diode (unlabeled) may be formed in the area between the Vdd and Vsub bonding pads for temperature sensing. The structure of the diode will be detailed further while referring to FIGS. 39-41. FIG. 39 shows an enlarged view of the upper-left portion of the device illustrated in FIG. 34, to further clarify the relationship between that diode and those bonding pads. As illustrated in FIG. 39, a diode bonding pad 3901 is provided between the Vdd and Vsub bonding pads. And a temperature sensing diode 3903 is placed below the diode pad 3901. Shaded region 3905 denotes an electrical connection between diode 3903 and the Vsub bonding pad. As will be explained further below, diode 3903 is also connected to diode bonding pad 3901 using a contact extending from the bottom of bonding pad into the surface of the substrate via a contact hole below the bonding pad.

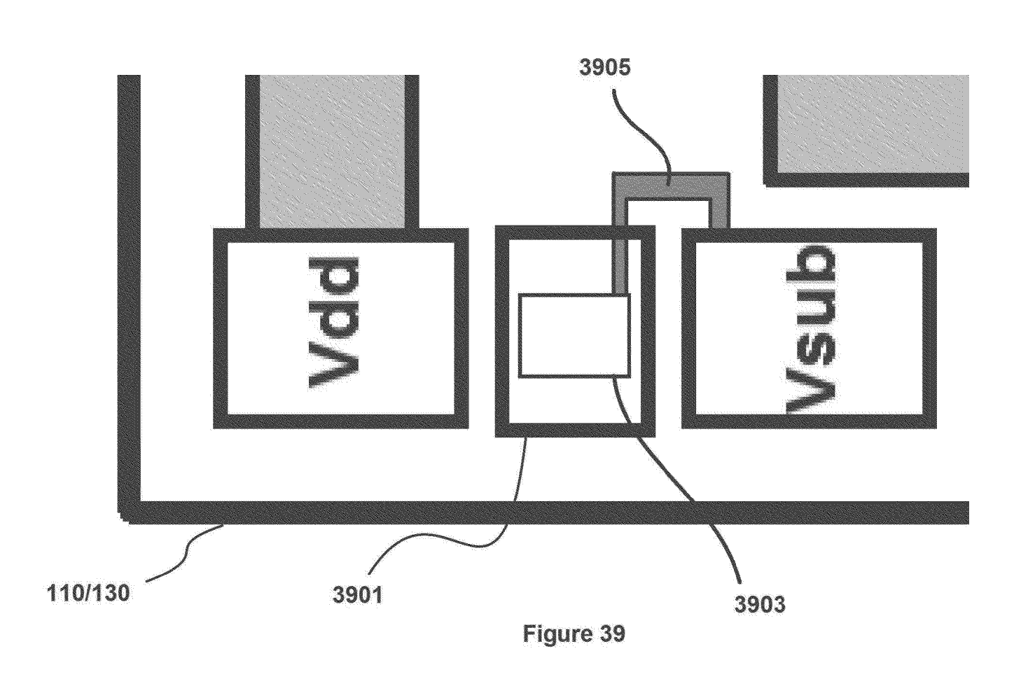

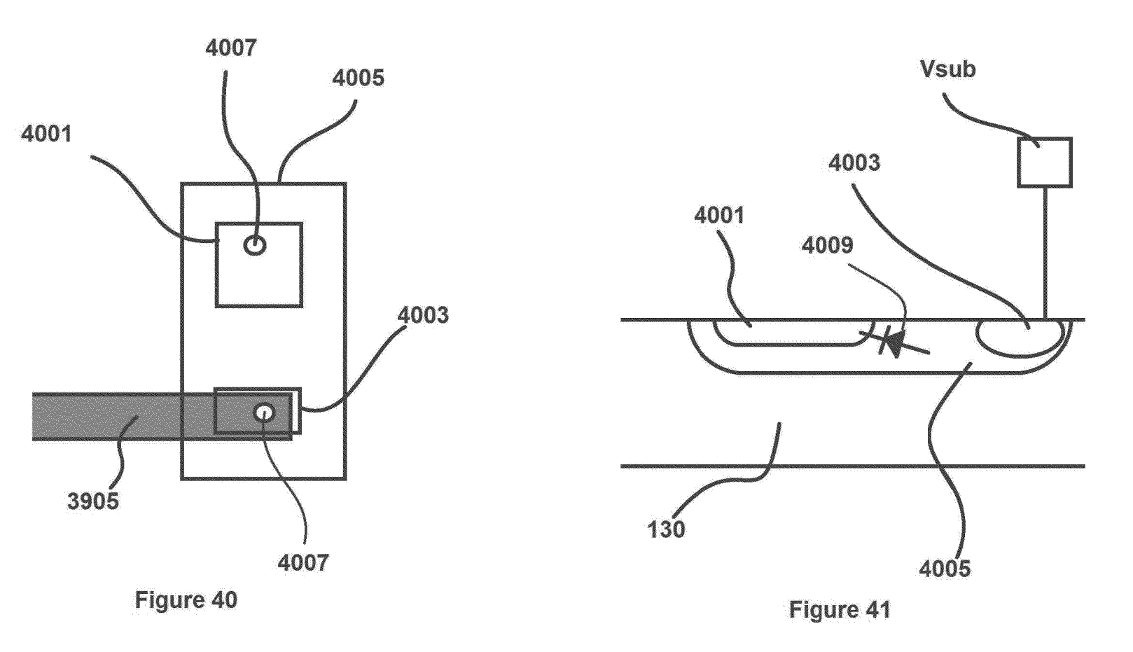

FIGS. 40 and 41 show top and side views, respectively, of diode 3903 formed in an n− device layer 130. The diode 3903 may be formed using known techniques for diode formation. An n+ region 4001 is implanted in device layer 130 to form a cathode. A p− region is implanted in layer 130 such that it completely surrounds the cathode 4001. A p+ region 4003 is also implanted in device layer 130 to ensure a good electrical contact between the p− anode via a contact hole 4007 to the metal layer 3905. Both contact holes 4007 are filled with an appropriate electrical conductor and extend from the top of regions 4001 and 4003 to the bottoms of bonding pad 3901 and metal layer 3905 respectively. Contact holes 4007 may be filled with the same metal used in forming bonding pad 3901 and metal connection 3905. Shaded electrical connection 3905 connects anode 4005 to the Vsub bonding pad. In FIG. 41, the schematic effect of diode 3903 is illustrated with symbol 4009.

In use, if a current of, for example, 50 μA is drawn through diode 3903, then a voltage will develop. It is known that Vsub will be set, preferably, at a fixed voltage of 5V. With the current and Vsub fixed, the voltage measured on diode bonding pad 3901 will be dependent on temperature according to known principles. Thus, a temperature sensor may be implemented with little extra effort and only a minimal power usage.

The pressure sensor described herein may also be provided with circuitry to prevent damage to the pressure sensor or its components from electrostatic discharge. Electrostatic discharges may occur in various voltages that, if significant enough and protection circuitry is absent, may cause damage to or render nonfunctional the sensor. Such discharges may be as high as 2000V or higher. It is known that with sufficient structure, electrostatic discharges of much higher voltage may be handled in a manner that will prevent damage. However, it may be cost-prohibitive to provide such structures. Thus, for purposes of the devices disclosed herein, it is assumed that handling discharges in the range between 0V and 2000V will be sufficient while maintaining the size and cost-effective structure of the device.

Such protection circuitry may be placed at or near the bonding pad so that if an excessive voltage is present, a transistor (not illustrated) will turn on and shunt the current directly into the device substrate to prevent the high voltage from being transferred to the other device circuitry. Transistors of this type may be placed at, below, or near the Vdd and Gnd bonding pads and attached to those pads.

In the examples above and in other embodiments of the present invention, a reference cavity may be formed in any one or more of the cap layers 810 or 160, oxide layers 150 and 140, and device layer 130. One or more of these layers may be omitted, for example oxide layer 150. Also, one or more other layers not shown may be included.

Directional references in the descriptions and claims in this disclosure—such as top, bottom, left, right, above, below, beside, etc.—are intended for simplicity and providing a frame of reference to the other portions of the disclosed apparatuses and to the FIGS. provided herewith, but are not intended to be limiting. For example, a person of ordinary skill in the art would recognize that, which the sensor may be illustrated in a particular orientation in each of the FIGS., the sensor may effectively function in multiple orientations, including orientations that are inverted, rotated, or otherwise altered from the orientations illustrated in the FIGS. Thus, the disclosure of directional references herein is not intended to be limiting.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

The processes described above can be embodied within additional hardware, such as a single integrated circuit (IC) chip, multiple ICs, an application specific integrated circuit (ASIC), or the like. Further, the order in which some or all of the process steps appear in each process should not be deemed limiting. Rather, it should be understood that some of the process steps can be executed in a variety of orders that are not all of which may be explicitly illustrated herein.

What has been described above includes examples of the implementations of the present invention. It is, of course, not possible to describe every conceivable combination of components or methods for purposes of describing the claimed subject matter, but many further combinations and permutations of the subject embodiments are possible. Accordingly, the claimed subject matter is intended to embrace all such alterations, modifications, and variations that fall within the spirit and scope of the appended claims. Moreover, the above description of illustrated implementations of this disclosure, including what is described in the Abstract, is not intended to be exhaustive or to limit the disclosed implementations to the precise forms disclosed. While specific implementations and examples are described herein for illustrative purposes, various modifications are possible that are considered within the scope of such implementations and examples, as those skilled in the relevant art can recognize.

In particular and in regard to the various functions performed by the above described components, devices, circuits, systems and the like, the terms used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter. In this regard, it will also be recognized that the various embodiments includes a system as well as a computer-readable storage medium having computer-executable instructions for performing the acts and/or events of the various methods of the claimed subject matter.

What is claimed is:

1. A pressure sensor comprising:
a first wafer portion having a backside cavity extending from a bottom side of the first wafer portion into the first wafer portion, the backside cavity defining an inside surface of a frame, the inside surface including a membrane;
a bonding layer over the first wafer portion;
a cap over the first wafer portion,
wherein a reference cavity is on an opposite side of the membrane from the backside cavity where the reference cavity has a width that is narrower in at least a first dimension than a width of the backside cavity in the first dimension; and
a eutectically bondable metal stack substantially covering the bottom side.

2. The sensor of claim 1, wherein the backside cavity is formed using DRIE; and
the bondable metal stack comprises a continuous path that surrounds the backside cavity on the bottom side.

3. The sensor of claim 2, wherein an edge of the bondable metal stack is recessed at least 1 μm and at most 20 μm from an edge of the backside cavity about a majority of a perimeter of the backside cavity.

4. The sensor of claim 2, wherein the bondable metal stack is recessed at least 1 μm and at most 20 μm from an outer edge of the bottom side of the first wafer portion about a majority of the perimeter of the bottom side.

5. A pressure sensor comprising:
a first wafer portion having a backside cavity extending from a bottom side of the first wafer portion into the first wafer portion, the backside cavity defining an inside surface of a frame, the inside surface including a membrane, wherein the membrane comprises a wafer layer that extends beyond the edges of the backside cavity and beyond the edges of the cap;
a bonding layer over the first wafer portion;
a cap over the first wafer portion,
wherein a reference cavity is on an opposite side of the membrane from the backside cavity where the reference cavity has a width that is narrower in at least a first dimension than a width of the backside cavity in the first dimension;
a plurality of bondpads contacting a top of the wafer layer;
a plurality of resistors formed within the membrane; and
a plurality of electrical connections, each electrical connection connecting at least one bond pad and at least one resistor;
wherein the electrical connections comprise ions implanted and annealed in the wafer layer in an appropriate pattern to form conductive traces.

6. A pressure sensor comprising:
a first wafer portion having a backside cavity extending from a bottom side of the first wafer portion into the first wafer portion, the backside cavity defining an inside surface of a frame, the inside surface including a membrane;
a bonding layer over the first wafer portion;
a cap over the first wafer portion,
wherein a reference cavity is on an opposite side of the membrane from the backside cavity where the reference cavity has a width that is narrower in at least a first dimension than a width of the backside cavity in the first dimension;
an implanted field shield in a top surface of the first wafer portion; and
a plurality of conductive traces that form one or more sense elements below the implanted field shield.

7. The sensor of claim 6 wherein the implanted field shield comprises an Arsenic implant

8. The sensor of claim 6 wherein the implanted field shield comprises a Phosphorus implant

9. A pressure sensor comprising:
a first wafer portion having a backside cavity extending from a bottom side of the first wafer portion into the first wafer portion, the backside cavity defining an inside surface of a frame, the inside surface including a membrane;
a bonding layer over the first wafer portion;
a cap over the first wafer portion,
wherein a reference cavity is on an opposite side of the membrane from the backside cavity where the reference cavity has a width that is narrower in at least a first dimension than a width of the backside cavity in the first dimension; and
a temperature sensing diode.

10. The sensor of claim 9, further comprising:
a substrate bond pad;
a temperature diode output bond pad; and
wherein the diode comprises an N+ implant and a P− implant connected between the temperature diode output pad and the substrate bond pad.

11. A pressure sensor comprising:
a first wafer portion having a backside cavity extending from a bottom side of the first wafer portion into the first wafer portion, the backside cavity defining an inside surface of a frame, the inside surface including a membrane;
a bonding layer over the first wafer portion;
a cap over the first wafer portion,
wherein a reference cavity is on an opposite side of the membrane from the backside cavity where the reference cavity has a width that is narrower in at least a first dimension than a width of the backside cavity in the first dimension; and
electrostatic discharge damage prevention circuitry.

12. The sensor of claim 11 wherein the circuitry comprises a plurality of transistors configured to control a current supply to all bond pads.

13. The sensor of claim 12 wherein the circuitry is configured to withstand electrostatic discharges to a bond pad, wherein the discharges are in the range of 0V to 2000V.
